(19) United States
(12) Patent Application Publication
(10) Pub. No.: US 2025/0261394 A1
(43) Pub. Date: Aug. 14, 2025

(54) DEVICES IMPLEMENTING SELECTIVE CAP LAYERS AND PROCESSES FOR IMPLEMENTING THE SAME

(71) Applicant: WOLFSPEED, INC., Durham, NC (US)

(72) Inventors: Jia GUO, New Hill, NC (US); Matt KING, Wake Forest, NC (US); Zongyang HU, New Hill, NC (US); Scott SHEPPARD, Chapel Hill, NC (US); Olof TORNBLAD, San Jose, CA (US)

(21) Appl. No.: 18/438,015

(22) Filed: Feb. 9, 2024

(51) Int. Cl. H01L 29/778; H01L 29/20; H01L 29/40; H01L 29/66

(52) U.S. Cl. CPC H10D 30/475; H10D 30/015; H10D 62/8503; H10D 64/111

(57) ABSTRACT

A device includes a substrate, a channel layer on the substrate, a barrier layer on the channel layer, a source electrically coupled to the barrier layer and/or the channel layer, a gate at least partially on the barrier layer, and a drain electrically coupled to the barrier layer and/or the channel layer. The device moreover includes a cap layer structured, configured, and/or arranged under an edge of the gate at a drain side.

### FIELD OF THE DISCLOSURE

The disclosure relates to devices implementing selective cap layers. The disclosure also relates to processes for implementing devices having selective cap layers.

### BACKGROUND OF THE DISCLOSURE

Group III-nitride based high-electron mobility transistors (HEMTs) are very promising candidates for high power amplifiers, radiofrequency (RF) applications, and also for low frequency high power switching applications since the material properties of Group III-nitrides, such as gallium nitride (GaN) and its alloys enable achievement of high voltage and high current along with high RF gain and linearity for RF applications. However, HEMTs still experience undesirable generation of electric field and/or generation of parasitic capacitances.

Accordingly, there is a need reduce generation of electric field and/or generation of parasitic capacitances to improve higher power performance in Group III-nitride HEMTs. Moreover, there is a need reduce generation of electric field and/or generation of parasitic capacitances to improve linearity in Group III-nitride HEMTs.

### SUMMARY OF THE DISCLOSURE

In one aspect, a device includes a substrate. The device in addition includes a channel layer on the substrate. The device moreover includes a barrier layer on the channel layer. The device also includes a source electrically coupled to the barrier layer and/or the channel layer. The device further includes a gate at least partially on the barrier layer. The device in addition includes a drain electrically coupled to the barrier layer and/or the channel layer. The device moreover includes a cap layer structured, configured, and/or arranged under an edge of the gate at a drain side and the cap layer extending on the barrier layer at least from the edge of the gate on the drain side. The device also includes where the cap layer does not extend to an edge of the gate on a source side.

In one aspect, a process includes providing a substrate. The process in addition includes arranging a channel layer on the substrate. The process moreover includes arranging a barrier layer on the channel layer. The process also includes electrically coupling a source to the barrier layer and/or the channel layer. The process further includes electrically coupling a drain to the barrier layer and/or the channel layer. The process in addition includes forming a cap layer on the barrier layer. The process moreover includes arranging a gate at least partially on the barrier layer and arranging an edge of the gate at a drain side on the cap layer. The process also includes where the cap layer extends at least from an edge of the gate on a drain side and the cap layer does not extend to an edge of the gate on a source side.

In one aspect, a device includes a substrate. The device in addition includes a channel layer on the substrate. The device moreover includes a barrier layer on the channel layer. The device also includes a source electrically coupled to the barrier layer and/or the channel layer. The device further includes a gate at least partially on the barrier layer. The device in addition includes a drain electrically coupled to the barrier layer and/or the channel layer. The device moreover includes a cap layer structured, configured, and/or arranged under an edge of the gate. The device also includes where the cap layer comprises an end portion. The device further includes where the gate is arranged on the end portion of the cap layer.

In one aspect, a process includes providing a substrate. The process in addition includes arranging a channel layer on the substrate. The process moreover includes arranging a barrier layer on the channel layer. The process also includes electrically coupling a source to the barrier layer and/or the channel layer. The process further includes electrically coupling a drain to the barrier layer and/or the channel layer. The process in addition includes forming a cap layer on the barrier layer. The process moreover includes arranging a gate at least partially on the barrier layer and arranging an edge of the gate at a drain side on the cap layer. The process also includes where the cap layer comprises an end portion. The process further includes where the gate is arranged on the end portion of the cap layer.

In one aspect, a device includes a substrate. The device in addition includes a channel layer on the substrate. The device moreover includes a barrier layer on the channel layer. The device also includes a source electrically coupled to the channel layer. The device further includes a gate having a bottom surface on the barrier layer. The device in addition includes a drain electrically coupled to the channel layer. The device moreover includes a cap layer on the barrier layer, where a portion of the bottom surface of the gate is directly on at least a portion of the cap layer.

In one aspect, a process includes providing a substrate. The process in addition includes arranging a channel layer on the substrate. The process moreover includes arranging a barrier layer on the channel layer. The process also includes electrically coupling a source electrically coupled to the channel layer. The process further includes electrically coupling a drain to the barrier layer and/or the channel layer. The process in addition includes forming a cap layer on the barrier layer. The process moreover includes arranging a gate having a bottom surface on the barrier layer. The process also includes where a portion of the bottom surface of the gate is directly on at least a portion of the cap layer.

In one aspect, a device includes a substrate. The device in addition includes a channel layer on the substrate. The device moreover includes a barrier layer on the channel layer. The device also includes a source electrically coupled to the barrier layer and/or the channel layer. The device further includes a gate at least partially on the barrier layer. The device in addition includes a drain electrically coupled to the barrier layer and/or the channel layer. The device moreover includes a cap layer structured, configured, and/or arranged under a drain side of the gate and the cap layer is not arranged under a source side of the gate.

In one aspect, a process includes providing a substrate. The process in addition includes arranging a channel layer on the substrate. The process moreover includes arranging a barrier layer on the channel layer. The process also includes electrically coupling a source to the barrier layer and/or the channel layer. The process further includes electrically coupling a drain to the barrier layer and/or the channel layer. The process in addition includes forming a cap layer on the barrier layer. The process moreover includes arranging a gate at least partially on the barrier layer. The process also includes where the cap layer is structured, configured, and/or arranged under a drain side of the gate and the cap layer is not arranged under a source side of the gate.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 shows a cross-sectional view of one aspect of a transistor according to the disclosure.

FIG. 2 shows a partial cross-sectional view the transistor according to FIG. 1.

FIG. 3 shows a partial cross-sectional view the transistor according to aspects of the disclosure.

FIG. 4 shows a partial cross-sectional view the transistor according to aspects of the disclosure.

FIG. 5 shows a partial cross-sectional view the transistor according to aspects of the disclosure during a first processing step.

FIG. 6 shows a partial cross-sectional view the transistor according to FIG. 5 during a second processing step.

FIG. 7 shows a partial cross-sectional view the transistor according to FIG. 5 during a third processing step.

FIG. 8 shows a partial cross-sectional view the transistor according to FIG. 5 during a fourth processing step.

FIG. 9 shows a partial cross-sectional view the transistor according to FIG. 5 during a fifth processing step.

FIG. 10 shows a partial cross-sectional view the transistor according to FIG. 5 during a sixth processing step.

FIG. 11 shows a partial cross-sectional view the transistor according to FIG. 5 during a seventh processing step.

FIG. 12 shows a partial cross-sectional view the transistor according to FIG. 5 during an eighth processing step.

FIG. 13 shows an exemplary process of implementing a transistor according to the disclosure.

FIG. 14 illustrates a graph of the electric field versus distance comparing the transistor according to the disclosure and a commensurate transistor implemented without the cap layer.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In addition to the type of structure, the characteristics of the semiconductor material from which a transistor is formed may also affect operating parameters. Of the characteristics that affect a transistor's operating parameters, the capacitance and the power gain may have an effect on a transistor's operational characteristics.

Capacitance may be a ratio of the change in an electric charge in a system to the corresponding change in an electric potential of the system. Reducing capacitance between an output and an input of a transistor may result in improved performance.

Power gain may be a measure of the ability to increase the power or amplitude of a signal from the input to the output port by adding energy converted from a power supply to the signal. It may be defined as the mean ratio of the signal amplitude or power at the output to the amplitude or power at the input. Increasing power gain of a transistor may result in improved performance. Other known power gain measures and characteristics are contemplated as well.

The disclosure includes both extrinsic and intrinsic semiconductors. Intrinsic semiconductors are undoped (pure). Extrinsic semiconductors are doped, meaning an agent has been introduced to change the electron and hole carrier concentration of the semiconductor at thermal equilibrium. Both p-type and n-type semiconductors are disclosed, with p-types having a larger hole concentration than electron concentration, and n-types having a larger electron concentration than hole concentration.

Silicon carbide (SiC) has excellent physical and electronic properties, which should theoretically allow production of electronic devices that can operate at higher temperatures, higher power, and higher frequency than devices produced from silicon (Si) or gallium arsenide (GaAs). The high electric breakdown field of about 4×E6 V/cm, high saturated electron drift velocity of about 2.0×E7 cm/sec and high thermal conductivity of about 4.9 W/cm−° K indicate that SiC would be suitable for high frequency and high power applications.

As used herein, the term “Group III-nitride” refers to those semiconducting compounds formed between nitrogen and one or more elements in Group III of the periodic table, usually aluminum (Al), gallium (Ga), and indium (In). The term also refers to binary, ternary, and quaternary compounds such as GaN, AlGaN, and AlInGaN. The Group III elements can combine with nitrogen to form binary (e.g., GaN), ternary (e.g., AlGaN), and quaternary (e.g., AlInGaN) compounds. These compounds may have empirical formulas in which one mole of nitrogen is combined with a total of one mole of the Group III elements. Accordingly, formulas such as AlxGa1−xN where 1>x>0 are often used to describe these compounds.

The disclosure is directed to devices implementing selective cap layers. The disclosure is further directed to processes for with devices implementing selective cap layers.

Further, the disclosure is directed to devices implementing selective cap layers to reduce generation of electric field. Further, the disclosure is further directed to processes for implementing devices with selective cap layers to reduce generation of electric field.

Further, the disclosure is directed to devices implementing selective cap layers to reduce generation of parasitic capacitances. Further, the disclosure is further directed to processes for implementing devices with selective cap layers to reduce generation of parasitic capacitances.

Further, the disclosure is directed to devices implementing selective cap layers for high breakdown voltage. Further, the disclosure is further directed to processes for implementing devices with selective cap layers for high breakdown voltage.

Additionally, the disclosure is directed to devices implementing selective cap layers for high power gain. Additionally, the disclosure is further directed to processes for implementing devices with selective cap layers for high power gain.

In aspects, the devices may include transistors, high-electron mobility transistors (HEMTs) devices, HEMT radiofrequency (RF) devices, gallium nitride (GaN) HEMT devices, GaN HEMT RF devices, and/or the like. In aspects, the devices may be implemented as discrete devices, monolithic microwave integrated circuit (MMIC) devices, and/or the like.

The disclosed device structures and process of implementing device structures may improve high power performance and linearity of devices, such as transistors, HEMT devices, HEMT RF devices, GaN HEMT devices, GaN HEMT RF devices, and/or the like through a reduction of an electrical field and minimization of parasitic capacitances.

The disclosed device structures and process of implementing device structures may improve device performance over current technology. In particular, the disclosed device structures and process of implementing device structures may include a selective cap layer around a gate edge at a drain side that may reduce peak electric field >10% and decrease Cgd (gate drain capacitance). The 10% lower peak electric field may increase the breakdown voltage and improve reliability.

Further, reducing Cgd may increase a power gain of the device. The reduced electron charge density also improves the linearity. Moreover, the reduced peak electric field on the drain side may also lower ionization of traps in this region, leading to a strong suppression of the dynamic trapping amplitude, critical for the linearity performance.

In aspects, the disclosed device structures and process of implementing device structures may utilize a selective cap layer around the gate edge at the drain side together with double gate feature.

In aspects, the disclosed device structures and process of implementing device structures may implement a cap layer in a source access region and part of the drain access region that may be etched before passivation layer deposition. By removing the cap layer in the source access region and part of the drain access region, a 2DEG concentration may be kept high in these regions for low on-state resistance and high power density. In aspects, this feature may decrease a peak electric field, increase off-state breakdown voltage, reduce Cg (gate capacitance) and may allow for higher operation voltage, higher frequency performance, higher power gain, and/or the like.

In aspects, the disclosed device structures and process of implementing device structures may include depositing a passivation layer after selectively removing the cap layer.

In aspects, the disclosed device structures and process of implementing device structures may include a thickness of the cap layer in the range from 1 nm to 30 nm. In aspects, the disclosed device structures and process of implementing device structures may be AlₓGa₁₋ₓN, where 0≤x≤1. In aspects, x may be constant in the range from 0% to 30%, graded from 0% to 30%, and/or the like.

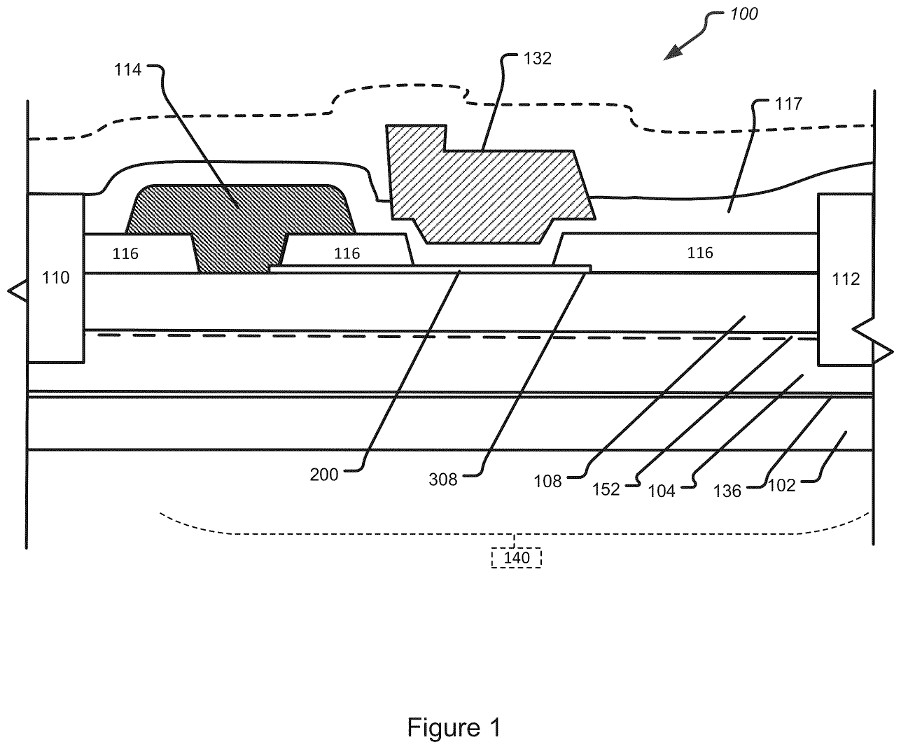

FIG. 1 shows a cross-sectional view of one aspect of a transistor according to the disclosure.

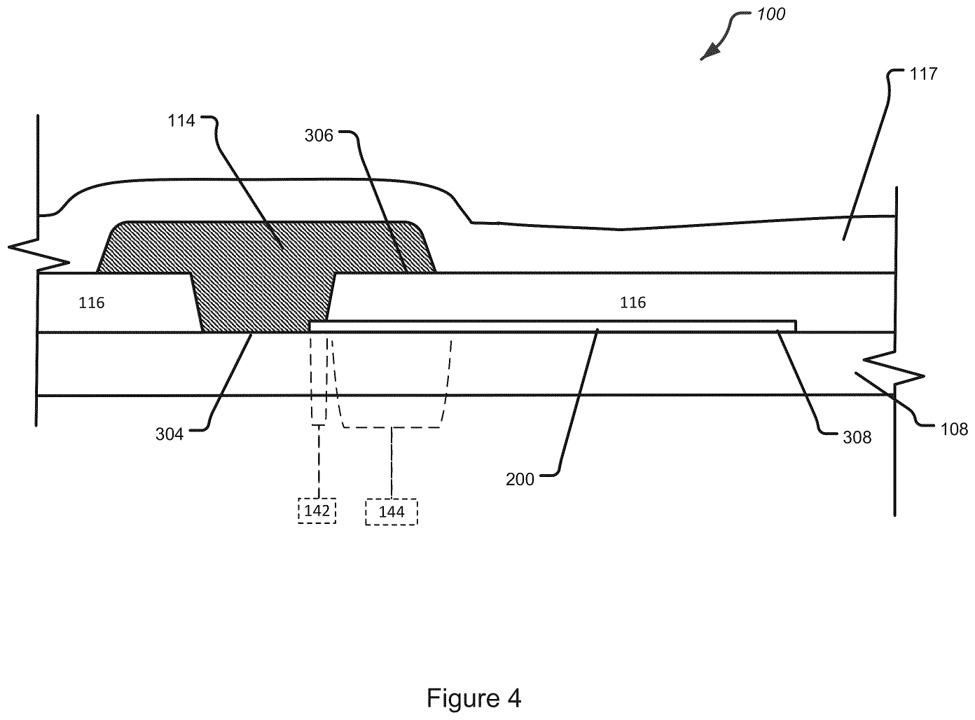

In particular, FIG. 1 shows a cross-sectional view of a transistor 100. The transistor 100 may include a substrate layer 102 and a channel layer 104. The transistor 100 may further include a barrier layer 108 arranged on the channel layer 104. In one aspect, the barrier layer 108 may be arranged directly on the channel layer 104. The transistor 100 may further include a source 110, a gate 114, and a drain 112. In one aspect, a bandgap of the channel layer 104 may be less than a bandgap of the barrier layer 108 to form a two-dimensional electron gas (2DEG) at a heterointerface 152 between the channel layer 104 and the barrier layer 108 when biased at an appropriate level. Further, the transistor 100 may include a field plate 132. In other aspects, as illustrated in FIG. 4, the transistor 100 may implemented without the field plate 132.

Additionally, the transistor 100 may include a cap layer 200. The cap layer 200 may be configured to improve performance of the transistor 100 over current technology. In particular, the cap layer 200 may be structured, configured, and/or arranged around an edge of the gate 114 at a drain side. In this regard, a drain side of the transistor 100 may be a side of the transistor 100 as illustrated in FIG. 1 between the gate 114 and the drain 112. Further, the cap layer 200 may be structured, configured, and/or arranged around a lower edge of the gate 114 at the drain side adjacent and/or on the barrier layer 108. On the other hand, a source side of the transistor 100 may be a side of the transistor 100 as illustrated in FIG. 1 between the gate 114 and the source 110.

Further, the cap layer 200 may be structured, configured, and/or arranged to reduce a peak electric field of the transistor 100 by more than 5%, 10%, 15%, 20%, or 25%. In aspects, the cap layer 200 may be structured, configured, and/or arranged to reduce a peak electric field of the transistor 100 by more than 5%-10%, 10%-15%, 15%-20%, or 20%-25%. In particular, the cap layer 200 may be structured, configured, and/or arranged to reduce a peak electric field of the transistor 100 in comparison to a commensurate transistor that does not implement the cap layer 200.

Additionally, the cap layer 200 may be structured, configured, and/or arranged to decrease Cgd (gate drain capacitance) of the transistor 100. The lower peak electric field may increase the breakdown voltage of the transistor 100; and the lower peak electric field may improve reliability of the transistor 100. In particular, the cap layer 200 may be structured, configured, and/or arranged to decrease Cgd (gate drain capacitance) of the transistor 100 in comparison to a commensurate transistor that does not implement the cap layer 200.

Further, reducing Cgd may increase a power gain of the transistor 100. The reduced electron charge density may also improve the linearity of the transistor 100. In particular, the transistor 100 may have improved linearity compared to a commensurate transistor that does not implement the cap layer 200.

Moreover, the reduced peak electric field on the drain side of the transistor 100 may also lower ionization of traps in this region of the transistor 100. In particular, the transistor 100 may also lower ionization of traps in this region of the transistor 100 compared to a commensurate transistor that does not implement the cap layer 200. In this regard, this may lead to a stronger suppression of a dynamic trapping amplitude of the transistor 100, which may be critical for a linearity performance of the transistor 100. In particular, the transistor 100 may have a stronger suppression of a dynamic trapping amplitude compared to a commensurate transistor that does not implement the cap layer 200.

In aspects, the cap layer 200 may be structured, configured, and/or arranged around an edge the gate 114 at the drain side. In aspects, the cap layer 200 may be structured, configured, and/or arranged to extend from an edge of the gate 114 on a drain side of the transistor 100. In aspects, the cap layer 200 may be structured, configured, and/or arranged to extend from an edge of the gate 114 on a drain side of the transistor 100 toward an edge of the gate 114 on a source side of the transistor 100. In aspects, the cap layer 200 may not fully extend to an edge of the gate 114 on the source side of the transistor 100. In aspects, the cap layer 200 may be structured, configured, and/or arranged under the gate 114 on a drain side of the transistor 100; and the cap layer 200 may not be arranged under the gate 114 on the source side of the transistor 100. In aspects, the vertical area under the gate 114 on the source side of the transistor 100 may be free of the cap layer 200.

In aspects, the cap layer 200 may have an end portion. In aspects, the gate 114 may be arranged on the end portion of the cap layer 200. In aspects, the gate 114 may be arranged on the end portion of the cap layer 200 between an edge of the gate 114 on a source side of the transistor 100 and an edge of the gate 114 on a drain side of the transistor 100.

In aspects, the transistor 100 may be implemented with double gate feature configuration. In other aspects, the transistor 100 may be implemented without a double gate feature configuration as illustrated in FIG. 4.

In aspects, the cap layer 200 may be structured, configured, and/or arranged to include a thickness in the range from 1 nm to 30 nm. In this regard, a dimension of thickness may be along an axis perpendicular to a surface of the barrier layer 108 on which the cap layer 200 is arranged. In aspects, the cap layer 200 may be structured, configured, and/or arranged to include a thickness in the range from 1 nm to 2 nm, 2 nm to 3 nm, 3 nm to 4 nm, 4 nm to 5 nm, 4 nm to 6 nm, 5 nm to 6 nm, 6 nm to 7 nm, 7 nm to 8 nm, 8 nm to 14 nm, 14 nm to 20 nm, 20 nm to 24 nm, or 24 nm to 30 nm. In aspects, the cap layer 200 may be structured, configured, and/or arranged to include a thickness greater than 1 nm, 2 nm, 3 nm, 4 nm, 5 nm, 6 nm, 10 nm, 15 nm, 20 nm, or 25 nm. In aspects, the cap layer 200 may be structured, configured, and/or arranged to include a thickness less than 2 nm, 3 nm, 4 nm, 5 nm, 6 nm, 7 nm, 10 nm, 15 nm, 20 nm, 25 nm, or 30 nm.

In aspects, the cap layer 200 may be structured, configured, and/or arranged with a material that includes AlₓGa₁₋ₓN, where 0≤x≤1. In aspects, x may be constant in the range from 0% to 10%, graded from 0% to 10%, and/or the like. In aspects, the cap layer 200 may be structured, configured, and/or arranged with the material that includes AlₓGa₁₋ₓN that is non-doped, P doped, or N doped. In aspects, the cap layer 200 may be structured, configured, and/or arranged with the material that includes AlₓGa₁₋ₓN implanted with P dopants or N dopants. In aspects, the cap layer 200 may be structured, configured, and/or arranged with GaN. In aspects, the cap layer 200 may be structured, configured, and/or arranged with AlGaN. In aspects, the cap layer 200 may be structured, configured, and/or arranged as a single layer, a single layer of material, multiple layers, multiple layers of material, multiple layers of different materials, multiple layers of the same material, and/or the like.

In aspects, the cap layer 200 may be arranged on an upper barrier layer surface 308 of the barrier layer 108. In aspects, the cap layer 200 may be arranged on the upper barrier layer surface 308 with intervening layers and structures therebetween. In aspects, the cap layer 200 may be arranged directly on the upper barrier layer surface 308. In aspects, the cap layer 200 may be arranged in the upper barrier layer surface 308.

In one aspect, the cap layer 200 may be structured and arranged partially in a protective layer 116 and/or partially under the protective layer 116. In one aspect, the cap layer 200 may be structured and arranged partially in the protective layer 116 and partially in the barrier layer 108. In one aspect, the cap layer 200 may be structured and arranged partially in the upper barrier layer surface 308 and partially in the barrier layer 108.

In one aspect, the cap layer 200 may be located on the gate-drain side 140 of the transistor 100 closer to the gate 114 than the drain 112. In aspects, the gate-drain side 140 may extend from at least from the gate 114 to the drain 112.

In one aspect, a portion of the cap layer 200 may be under the gate 114. In one aspect, the cap layer 200 may be located anywhere in the transistor 100 including above an interface between the barrier layer 108 and the channel layer 104. In one aspect, the cap layer 200 may be located anywhere in the transistor 100 including in, on, and/or between the barrier layer 108 and/or the channel layer 104.

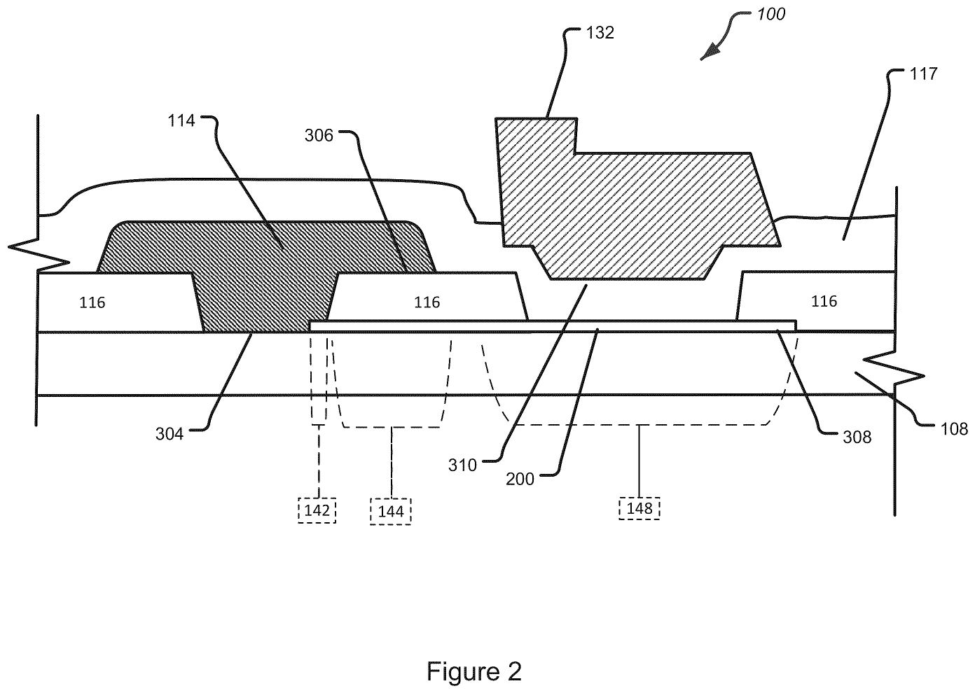

FIG. 2 shows a partial cross-sectional view the transistor according to FIG. 1.

The aspects of the transistor 100 and the cap layer 200 illustrated in FIG. 2 may optionally include other aspects of the transistor 100 and the cap layer 200 described and illustrated herein. Further, other aspects of the transistor 100 and the cap layer 200 illustrated and described herein may optionally include the aspects of the transistor 100 and the cap layer 200 described and illustrated with respect to FIG. 2. In aspects, the gate 114 may include a bottom surface on the barrier layer 108. In aspects, the cap layer 200 may be on the barrier layer 108. In aspects, a portion of the bottom surface of the gate 114 may be directly on at least a portion of the cap layer 200. In aspects, the cap layer 200 may include multiple layers and subset of the multiple layers may be under the gate 114. In aspects, the cap layer 200 may include multiple layers and all of the multiple layers of the cap layer 200 may be under the gate 114. In aspects, the barrier layer 108 may include multiple layers. In aspects, there may be intervening layers between the gate 114 the barrier layer 108.

With respect to FIG. 2, the gate 114 may include a lower gate surface 304. In aspects, the lower gate surface 304 may be arranged on the upper barrier layer surface 308. In aspects, the lower gate surface 304 may be arranged on the upper barrier layer surface 308 with intervening layers and structures therebetween. In aspects, the lower gate surface 304 may be arranged directly on the upper barrier layer surface 308. In aspects, the lower gate surface 304 may be the closest portion of the gate 114 to the barrier layer 108. In aspects, other portions of the gate 114 may extend from the lower gate surface 304 toward a top of the gate 114.

In aspects, the cap layer 200 may be structured, configured, and/or arranged to extend from an edge of the lower gate surface 304 on a drain side of the transistor 100. In aspects, the cap layer 200 may be structured, configured, and/or arranged to extend from an edge of the lower gate surface 304 on a drain side of the transistor 100 toward a source side of the transistor 100. In aspects, the cap layer 200 may not fully extend to an edge of the lower gate surface 304 on the source side of the transistor 100. In aspects, the cap layer 200 may be structured, configured, and/or arranged under the lower gate surface 304 on a drain side of the transistor 100; and the cap layer 200 may not be arranged under the lower gate surface 304 on the source side of the transistor 100. In aspects, the vertical area under the lower gate surface 304 on the source side of the transistor 100 may be free of the cap layer 200.

In aspects, the cap layer 200 may include a cap layer gate portion 142. In aspects, the cap layer gate portion 142 may be arranged under the lower gate surface 304. In aspects, the lower gate surface 304 may be arranged on the cap layer gate portion 142. In aspects, the lower gate surface 304 may be arranged on the cap layer gate portion 142 with intervening layers and structures therebetween. In aspects, the lower gate surface 304 may be arranged directly on the cap layer gate portion 142.

In aspects, the cap layer gate portion 142 may be an end portion of the cap layer 200. In aspects, the lower gate surface 304 may be arranged on the end portion of the cap layer 200 or the cap layer gate portion 142. In aspects, the lower gate surface 304 may be arranged on the end portion of the cap layer 200 or the cap layer gate portion 142 that may be arranged between an edge of the lower gate surface 304 on a source side of the transistor 100 and an edge of the lower gate surface 304 on a drain side of the transistor 100.

In aspects, part of the lower gate surface 304 may be arranged on the upper barrier layer surface 308; and part of the lower gate surface 304 may be arranged on the cap layer gate portion 142. In aspects, a majority of the lower gate surface 304 may be arranged on the upper barrier layer surface 308; and minority part of the lower gate surface 304 may be arranged on the cap layer gate portion 142.

In aspects, the gate 114 may include a secondary gate surface 306. In aspects, the secondary gate surface 306 may be arranged vertically above the lower gate surface 304. In other words, the secondary gate surface 306 may be arranged between the lower gate surface 304 and an upper surface of the gate 114.

In aspects, the secondary gate surface 306 may be arranged on the protective layer 116. In aspects, the secondary gate surface 306 may be arranged on the protective layer 116 with intervening layers and structures therebetween. In aspects, the secondary gate surface 306 may be arranged directly on the protective layer 116.

In aspects, the cap layer 200 may be arranged under the secondary gate surface 306. In aspects, the cap layer 200 may include a secondary gate cap layer portion 144 secondary gate cap layer portion 144. In aspects, the secondary gate cap layer portion 144 may be partially arranged under the secondary gate surface 306. In aspects, the secondary gate cap layer portion 144 may be arranged under the secondary gate surface 306.

In aspects, the field plate 132 may include a lower field plate surface 310. In aspects, the lower field plate surface 310 may be arranged on a spacer layer 117. In aspects, the lower field plate surface 310 may be arranged on the spacer layer 117 with intervening layers and structures therebetween. In aspects, the lower field plate surface 310 may be arranged directly on the spacer layer 117.

In aspects, the cap layer 200 may be arranged partially under the field plate 132. In aspects, the cap layer 200 may include a field plate cap layer portion 148. In aspects, the field plate cap layer portion 148 may be arranged partially under the field plate 132. In aspects, the field plate cap layer portion 148 may be arranged under the field plate 132. In aspects, the field plate cap layer portion 148 may be arranged completely under the field plate 132. In aspects, the field plate cap layer portion 148 may be arranged partially under the lower field plate surface 310. In aspects, the field plate cap layer portion 148 may be arranged under the lower field plate surface 310. In aspects, the field plate cap layer portion 148 may be arranged completely under the lower field plate surface 310.

In aspects, the cap layer 200 may include the cap layer gate portion 142 and the secondary gate cap layer portion 144. In aspects, the cap layer gate portion 142 may be connected to the secondary gate cap layer portion 144 with an intervening portion of the cap layer 200. In aspects, the cap layer gate portion 142 may be connected to the secondary gate cap layer portion 144. In aspects, the cap layer gate portion 142 may be directly connected to the secondary gate cap layer portion 144. In aspects, the cap layer gate portion 142 may be connected to the secondary gate cap layer portion 144 and be a continuous portion of the cap layer 200.

In aspects, the cap layer 200 may include the field plate cap layer portion 148 and the secondary gate cap layer portion 144. In aspects, the field plate cap layer portion 148 may be connected to the secondary gate cap layer portion 144 with an intervening portion of the cap layer 200. In aspects, the field plate cap layer portion 148 may be connected to the secondary gate cap layer portion 144. In aspects, the field plate cap layer portion 148 may be directly connected to the secondary gate cap layer portion 144. In aspects, the field plate cap layer portion 148 may be connected to the secondary gate cap layer portion 144 and be a continuous portion of the cap layer 200.

In aspects, the cap layer 200 may include the field plate cap layer portion 148 and an additional portion of the cap layer 200 extending from the field plate cap layer portion 148 toward the drain 112. In aspects, the field plate cap layer portion 148 may be connected to the additional portion of the cap layer 200. In aspects, the field plate cap layer portion 148 may be connected to the additional portion of the cap layer 200. In aspects, the field plate cap layer portion 148 may be directly connected to the additional portion of the cap layer 200. In aspects, the field plate cap layer portion 148 may be connected to the additional portion of the cap layer 200 and be a continuous portion of the cap layer 200.

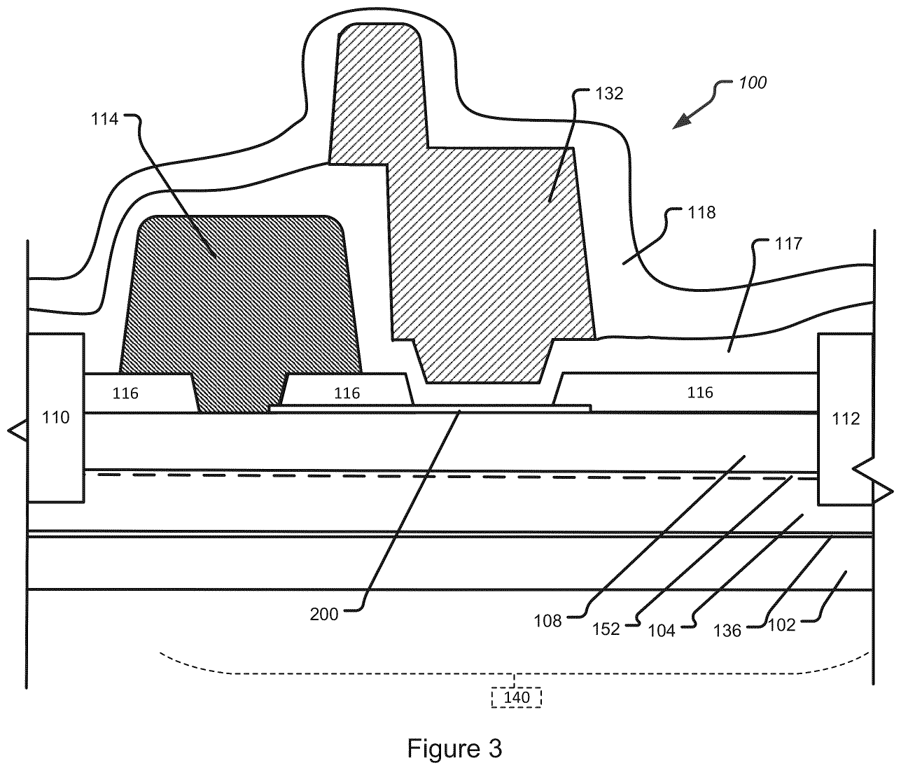

FIG. 3 shows a partial cross-sectional view the transistor according to aspects of the disclosure.

The aspects of the transistor 100 and the cap layer 200 illustrated in FIG. 3 may optionally include other aspects of the transistor 100 and the cap layer 200 described and illustrated herein. Further, other aspects of the transistor 100 and the cap layer 200 illustrated and described herein may optionally include the aspects of the transistor 100 and the cap layer 200 described and illustrated with respect to FIG. 3.

In particular, FIG. 3 illustrates an implementation of the transistor 100 where the field plate 132 includes a portion extending over the gate 114. Further, the transistor 100 illustrated in FIG. 3 may include the cap layer 200 as described herein. In aspects, the gate 114 may be implemented with a larger configuration. In aspects, the field plate 132 may be implemented with a larger configuration.

FIG. 4 shows a partial cross-sectional view the transistor according to aspects of the disclosure.

The aspects of the transistor 100 and the cap layer 200 illustrated in FIG. 4 may optionally include other aspects of the transistor 100 and the cap layer 200 described and illustrated herein. Further, other aspects of the transistor 100 and the cap layer 200 illustrated and described herein may optionally include the aspects of the transistor 100 and the cap layer 200 described and illustrated with respect to FIG. 4.

In particular, FIG. 4 illustrates an implementation of the transistor 100 without an implementation of the field plate 132. Additionally, the transistor 100 illustrated in FIG. 4 may implement the cap layer 200 as described herein.

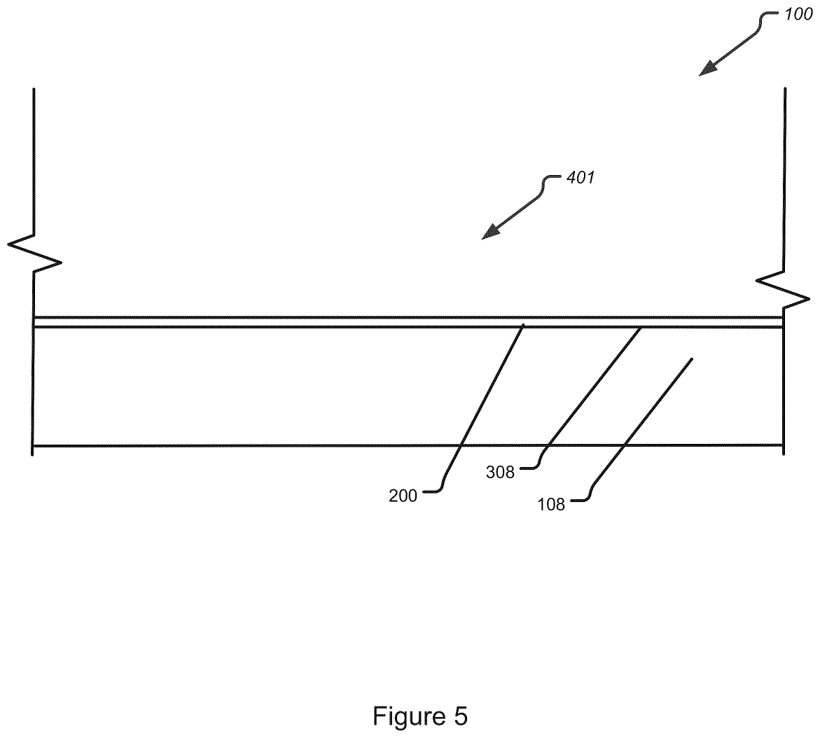

FIG. 5 shows a partial cross-sectional view the transistor according to aspects of the disclosure during a first processing step.

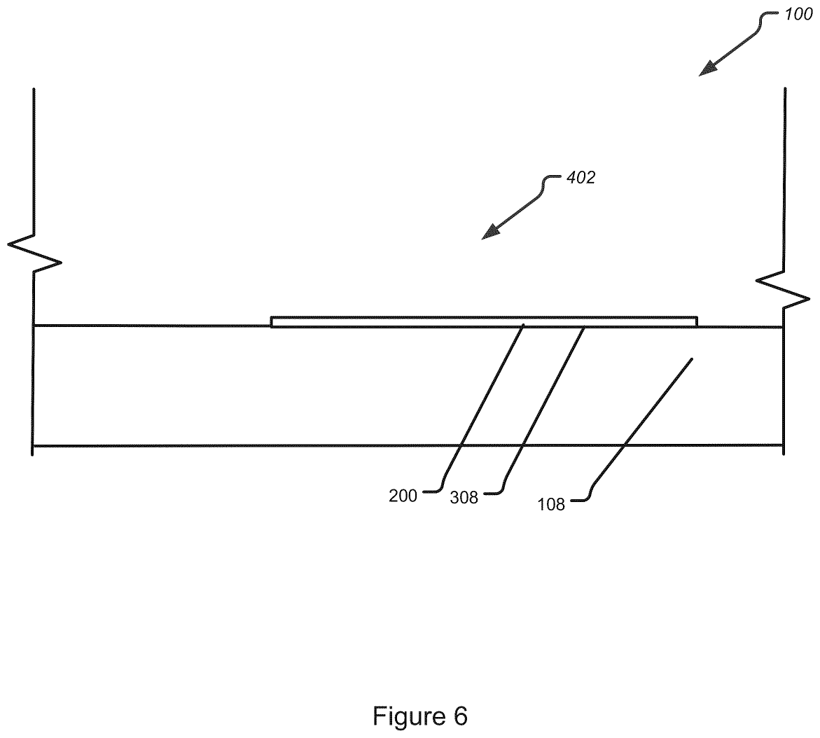

FIG. 6 shows a partial cross-sectional view the transistor according to FIG. 5 during a second processing step.

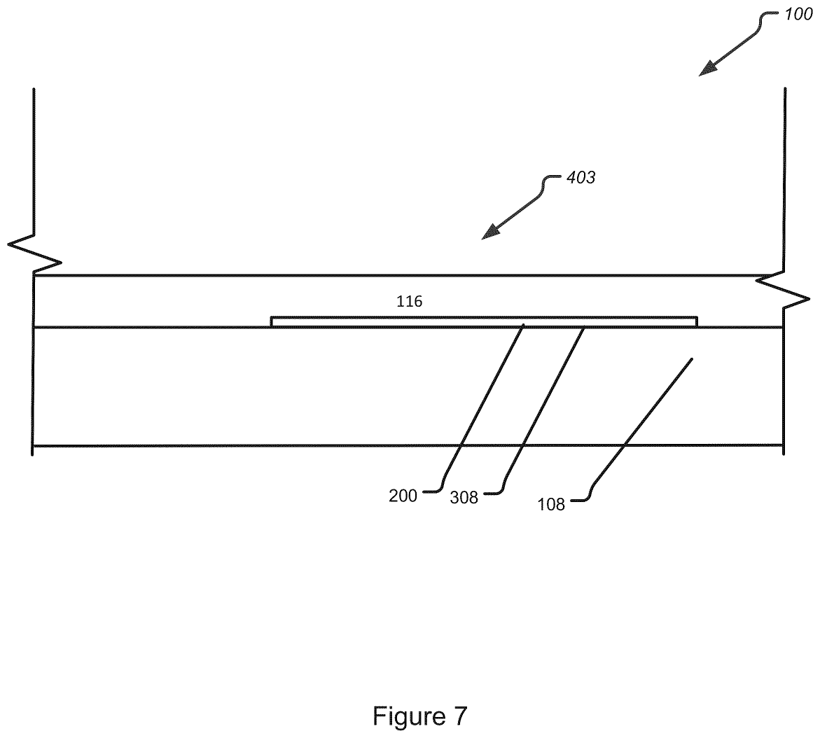

FIG. 7 shows a partial cross-sectional view the transistor according to FIG. 5 during a third processing step.

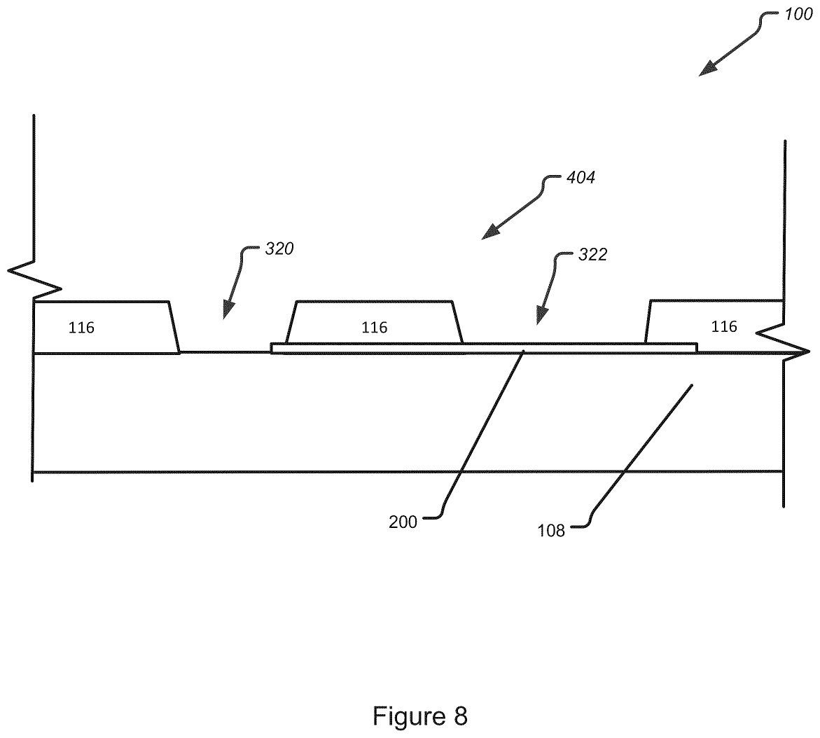

FIG. 8 shows a partial cross-sectional view the transistor according to FIG. 5 during a fourth processing step.

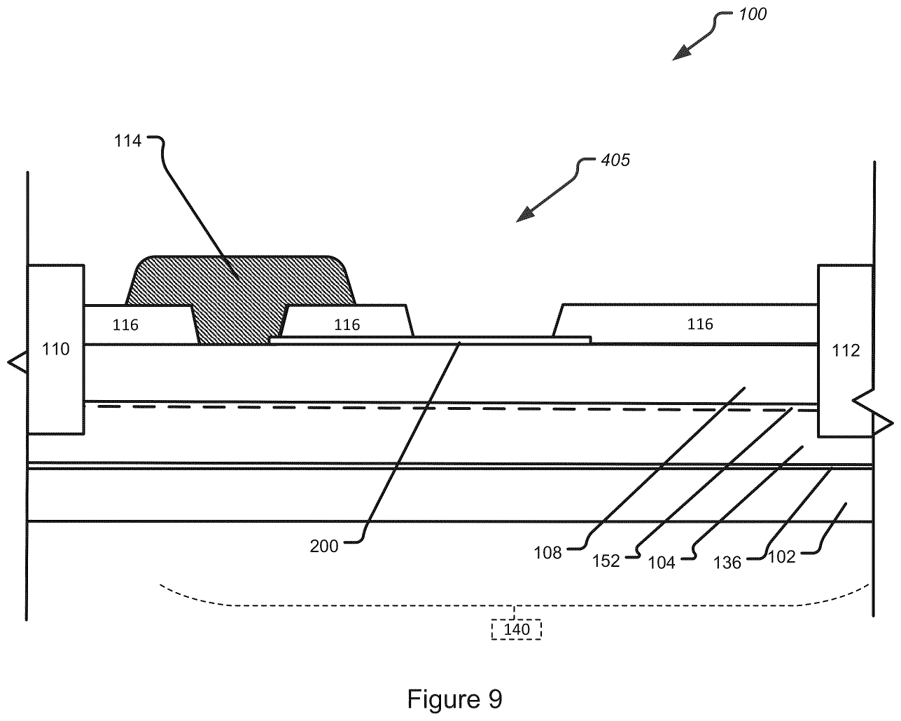

FIG. 9 shows a partial cross-sectional view the transistor according to FIG. 5 during a fifth processing step.

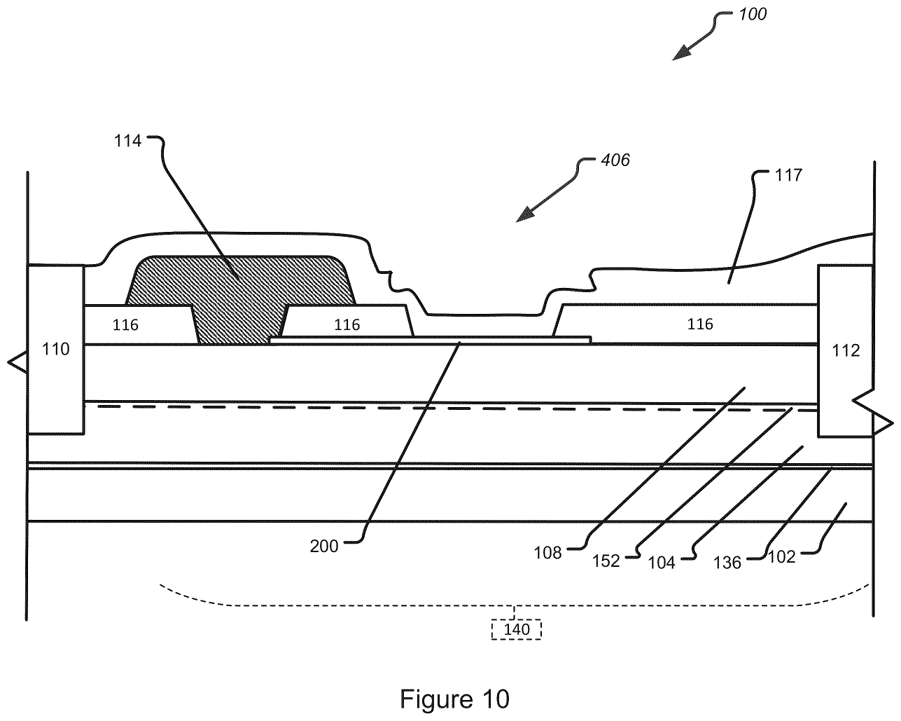

FIG. 10 shows a partial cross-sectional view the transistor according to FIG. 5 during a sixth processing step.

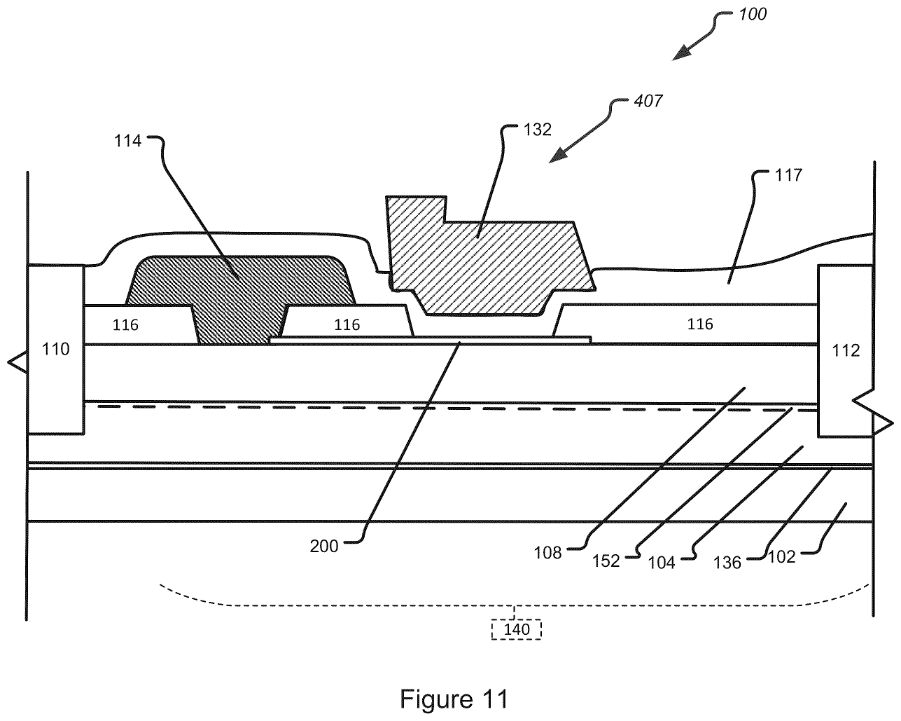

FIG. 11 shows a partial cross-sectional view the transistor according to FIG. 5 during a seventh processing step.

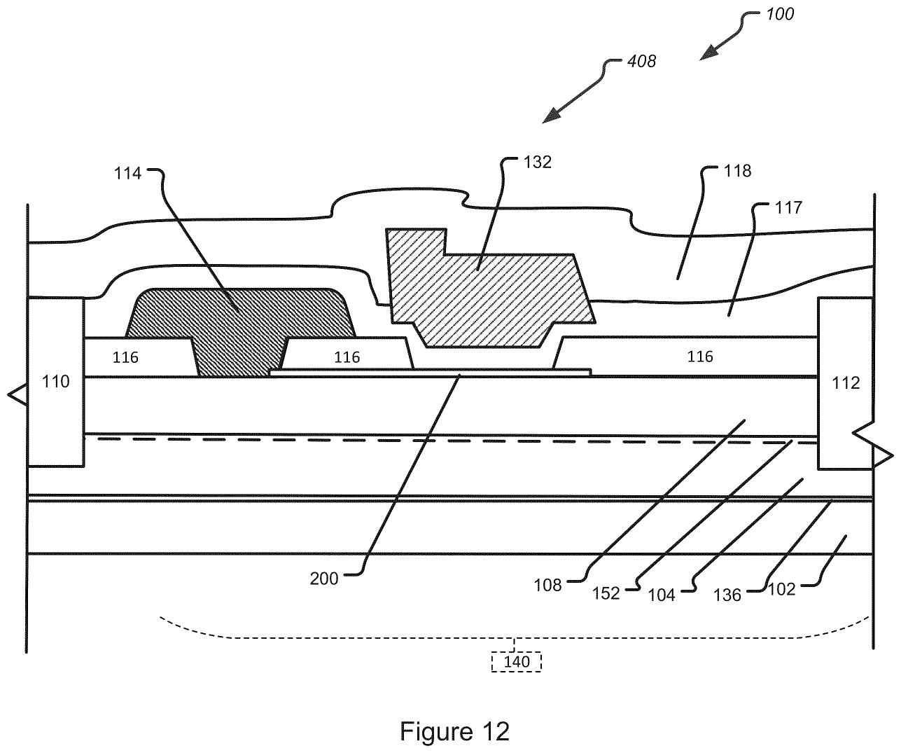

FIG. 12 shows a partial cross-sectional view the transistor according to FIG. 5 during an eighth processing step.

The aspects of the transistor 100 and the cap layer 200 illustrated in FIGS. 5-12 may optionally include other aspects of the transistor 100 and the cap layer 200 described and illustrated herein. Further, other aspects of the transistor 100 and the cap layer 200 illustrated and described herein may optionally include the aspects of the transistor 100 and the cap layer 200 described and illustrated with respect to FIGS. 5-12.

In particular, FIG. 5 shows a partial cross-sectional view the transistor according to aspects of the disclosure during a first processing step 401, FIG. 6 shows a partial cross-sectional view the transistor according to FIG. 5 during a second processing step 402, FIG. 7 shows a partial cross-sectional view the transistor according to FIG. 5 during a third processing step 403, FIG. 8 shows a partial cross-sectional view the transistor according to FIG. 5 during a fourth processing step 404, FIG. 9 shows a partial cross-sectional view the transistor according to FIG. 5 during a fifth processing step 405, FIG. 10 shows a partial cross-sectional view the transistor according to FIG. 5 during a sixth processing step 406, FIG. 11 shows a partial cross-sectional view the transistor according to FIG. 5 during a seventh processing step 407, and FIG. 12 shows a partial cross-sectional view the transistor according to FIG. 5 during an eighth processing step 408.

In aspects, the cap layer 200 may be structured, configured, and/or arranged in a source access region and part of a drain access region as part of the first processing step 401 illustrated in FIG. 5. In other words, the cap layer 200 may be arranged on the upper barrier layer surface 308 and/or the entirety of the upper barrier layer surface 308.

In one aspect, the cap layer 200 may include the same material as the barrier layer 108. In one aspect, the cap layer 200 may include a different material than the barrier layer 108. In one aspect, the cap layer 200 may include a Group III-nitride material, such as AlGaN that is regrown and may have the same composition as the barrier layer 108. In one aspect, the cap layer 200 may include a Group III-nitride material, such as AlGaN, that is regrown and may have a different composition as the barrier layer 108.

In some aspects, the cap layer 200 can extend uniformly, non-uniformly, and/or a changing fashion with respect to composition, doping, and/or thickness. In aspects, the cap layer 200 may be formed using known semiconductor growth techniques such as Metalorganic Chemical Vapor Deposition (MOCVD), Hydride Vapor Phase Epitaxy (HVPE), Molecular Beam Epitaxy (MBE), and/or the like. In aspects, the cap layer 200 may be formed with Lateral Epitaxial Overgrowth (LEO). In aspects, the cap layer 200 may include hot wall epitaxy.

Thereafter, the cap layer 200 may be etched. In particular, the cap layer 200 may be etched in the source access region and part of the drain access region as part of the second processing step 402 illustrated in FIG. 6. By removing the cap layer 200 in the source access region and part of the drain access region, a 2DEG concentration of the transistor 100 may be kept high in these regions for low on-state resistance and high power density. In aspects, this feature may decrease a peak electric field, increase off-state breakdown voltage, reduce Cg (gate capacitance) and may allow for higher operation voltage, higher frequency performance, higher power gain, and/or the like of the transistor 100. Further, etching the cap layer 200 may form the cap layer gate portion 142, the secondary gate cap layer portion 144, and/or the field plate cap layer portion 148. The second processing step 402 may be implemented before passivation layer deposition that may include the protective layer 116.

Thereafter, as part of the third processing step 403 illustrated in FIG. 7, the protective layer 116 may be arranged on the cap layer 200, the barrier layer 108, and/or the upper barrier layer surface 308. In aspects, the disclosed device structures and process of implementing device structures may include depositing a passivation layer after selectively remove the cap layer. In particular, the third processing step 403 may be implemented after the second processing step 402.

As illustrated in FIG. 8, the fourth processing step 404 may include forming a gate opening 320 and a field plate opening 322. For example, a layer of photoresist may be formed on the protective layer 116 and patterned to form the gate opening 320 and the field plate opening 322. Thereafter, the protective layer 116 may be selectively etched through the gate opening 320 and the field plate opening 322, for example using a dry etch, a reactive ion etch, and/or inductively coupled plasma, and/or the like to form the gate opening 320 and the field plate opening 322 in the protective layer 116. In aspects, the gate opening 320 and/or the field plate opening 322 may partly form a double gate implementation of the gate 114.

In aspects, a sacrificial dielectric layer may be blanket deposited over the protective layer 116 to fill the gate opening 320 and the field plate opening 322. The sacrificial dielectric layer may be formed of the same material as the protective layer 116. For example, both the sacrificial dielectric layer and the protective layer 116 may be formed of silicon nitride.

In aspects, a sacrificial dielectric layer maybe anisotropically etched, for example using dry etch, a reactive ion etch, and/or inductively coupled plasma, to remove portions of the sacrificial dielectric layer except for side portions on inner surfaces of the gate opening 320 of the protective layer 116 and side portions on inner surfaces of the field plate opening 322 of the protective layer 116 to form a gate aperture and a field plate aperture having rounded or beveled edges. The protective layer 116 along with the side portions together form a surface dielectric layer on the upper barrier layer surface 308.

Referring to FIG. 9, the fifth processing step 405 may include providing a metal, such as gold, that may be deposited and patterned to form the gate 114 on the protective layer 116. The gate 114 may extend through the gate opening 320 to contact the barrier layer 108. In particular, the lower gate surface 304 may extend through the gate opening 320 to contact the barrier layer 108.

With reference to FIG. 10, the sixth processing step 406 may include forming the spacer layer 117. In particular, the spacer layer 117 may be blanket deposited over the protective layer 116 and the gate 114. The spacer layer 117 may extend through the field plate opening 322 to contact the barrier layer 108 and/or the cap layer 200.

Referring to FIG. 11, the seventh processing step 407 may include forming the field plate 132. In particular, a metal, such as gold, may be deposited on the spacer layer 117 above the field plate opening 322 and patterned to form the field plate 132. The field plate 132 may be separated from the barrier layer 108 within the field plate opening 322 by a distance corresponding to a thickness of the spacer layer 117. The field plate 132 may be laterally spaced apart from the gate 114 approximately equal to the thickness of the spacer layer 117. Accordingly, the field plate 132 may be self-aligned to the gate 114. In aspects, the field plate 132, the gate opening 320, and the field plate opening 322 may partly form a double gate implementation of the gate 114.

As illustrated in FIG. 12, the eighth processing step 408 may include forming a layer 118. In particular, the layer 118, such as a layer of SiON, may be formed over the field plate 132 and the spacer layer 117.

In one aspect, the cap layer 200 may be located anywhere in the transistor 100 including above an interface between the barrier layer 108 and the channel layer 104. In one aspect, the cap layer 200 may be located anywhere in the transistor 100 including in, on, and/or between the barrier layer 108 and/or the channel layer 104. However, for brevity of disclosure, the cap layer 200 may be illustrated and described in relation to an exemplary location.

In one aspect, the channel layer 104 is a Group III-nitride material, such as GaN, and the barrier layer 108 is a Group III-nitride material, such as AlGaN or AlN. In some aspects, there are intervening layer(s) or region(s) between the substrate layer 102 and the channel layer 104, such as the nucleation layer 136. In one aspect, there are intervening layer(s) or region(s) (not shown) between the channel layer 104 and the barrier layer 108. In one aspect, the barrier layer 108 is made of multiple layers, such as an AlN barrier layer on the channel layer 104, and an AlGaN layer on the AlN barrier layer. In one aspect, there are intervening layer(s) or region(s) between the barrier layer 108 and a protective layer 116 and/or the source 110, the gate 114 and/or the drain 112. In one aspect, the composition of these layers can be step-wise or continuously graded. In one aspect, the barrier layer 108 can start with a higher percentage of Al near the channel layer 104 and decrease in Al percentage away from the channel layer 104. In aspects, the channel layer 104 may be defined as a buffer layer.

In aspects of the transistor 100 of the disclosure, the substrate layer 102 may be made of Silicon Carbide (SiC) or sapphire. In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. In one aspect, the substrate layer 102 may be formed of SiC selected from the group of 6H, 4H, 15R, 3C SiC, or the like. In another aspect, the substrate layer 102 may be GaAs, GaN, or other material suitable for the applications described herein. In another aspect, the substrate layer 102 may include sapphire, spinel, ZnO, silicon, or any other material capable of supporting growth of Group III-nitride materials.

On the substrate layer 102, the channel layer 104, and/or a nucleation layer 136, may be formed. In one aspect, the channel layer 104 is formed on the substrate layer 102. In one aspect, the channel layer 104 is formed directly on the substrate layer 102. In one aspect, the nucleation layer 136 may be formed on the substrate layer 102. In one aspect, the nucleation layer 136 may be formed directly on the substrate layer 102. Intervening layer(s) and/or region(s) are possible throughout the described structures.

In aspects of the transistor 100 of the disclosure, the nucleation layer 136 may be formed on the substrate layer 102 to reduce a lattice mismatch between the substrate layer 102 and a next layer in the transistor 100. The nucleation layer 136 may include many different materials, such as Group III-nitride materials, with a suitable material being Al_{z}Ga_{1-z}N (0<=z<=1). The nucleation layer 136 may be formed on the substrate layer 102 using known semiconductor growth techniques such as Metalorganic Chemical Vapor Deposition (MOCVD), Hydride Vapor Phase Epitaxy (HVPE), Molecular Beam Epitaxy (MBE), and/or the like. In further aspects, there may be intervening layers between the nucleation layer 136 and the substrate layer 102. In further aspects, there may be intervening layers between the nucleation layer 136 and the channel layer 104.

The channel layer 104 may be a group Ill-nitride, such as GaN, Aluminum Gallium Nitride (AlGaN), Aluminum Nitride (AlN), AlₓGa_{y}In_{(1-x-y)}N (where 0<=x<=1, 0<=y<=1, x+y<=1), AlₓIn_{y}Ga_{1-x-y}N (where 0<=x<=1 and 0<=y<=1), and the like, or another suitable material and may also include a nucleation layer 136 of a group III-nitride material, such as AlN. In one aspect, the channel layer 104 is formed of AlGaN. The channel layer 104 may be a p-type material, or alternatively can be undoped. In one aspect, an AlN implementation of the nucleation layer 136 may be used to adhere to the substrate layer 102 and may help grow the channel layer 104. The channel layer 104 may bind to the substrate layer 102. In one aspect, the nucleation layer 136 may be AlGaN.

In one aspect, the channel layer 104 may be high purity GaN. In one aspect, the channel layer 104 may be high purity GaN that may be a low-doped n-type. In one aspect, the channel layer 104 may also use a higher band gap Group III-nitride layer as a back barrier, such as an AlGaN back barrier, on the other side of the channel layer 104 from the barrier layer 108 to achieve better electron confinement.

In aspects of the transistor 100 of the disclosure, on the channel layer 104, the barrier layer 108 may be formed. In one aspect, the barrier layer 108 may be formed directly on the channel layer 104. The barrier layer 108 may provide an additional layer between the channel layer 104 and the source 110, the drain 112, and the gate 114. The barrier layer 108 may be AlGaN, AlN, a Group III-nitride, InAlGaN, or another suitable material. In one aspect, the barrier layer 108 may be AlGaN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, a bandgap of the channel layer 104 may be less than a bandgap of the barrier layer 108. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, additional Group III-nitride layer(s) or region(s) and/or other layer(s) or region(s) of different materials are possible on the barrier layer 108 and/or in the overall structure. Any of the layers and/or regions can have uniform, non-uniform, graded and/or changing composition, thicknesses, and/or doping.

In aspects of the transistor 100 of the disclosure, the source 110 and/or the drain 112 may be connected directly to the barrier layer 108. In one aspect, the source 110 and/or drain 112 may be connected indirectly to the barrier layer 108. In one aspect, the barrier layer 108 may include a region under the source 110 and/or drain 112 that is an N+ material. In one aspect, the barrier layer 108 may include a region under the source 110 and/or drain 112 that is Si doped.

In aspects of the transistor 100 of the disclosure, the source 110 and/or the drain 112 may be connected directly to the channel layer 104. In one aspect, the source 110 and/or drain 112 may be connected indirectly to the channel layer 104. In one aspect, the channel layer 104 may include a region under the source 110 and/or drain 112 that is an N+ material. In one aspect, the channel layer 104 may include a region under the source 110 and/or drain 112 that is Si doped.

To protect and separate the gate 114 and the drain 112, the protective layer 116 may be arranged on the barrier layer 108, on a side opposite the channel layer 104, adjacent the gate 114 and the drain 112. The protective layer 116 may be a passivation layer made of SiN, AlO, SiO, SiO₂, AlN, SiON, or the like, or a combination incorporating multiple layers thereof. In one aspect, the protective layer 116 is a passivation layer made of SiN. In one aspect, the protective layer 116 can be deposited using MOCVD, plasma chemical vapor deposition (CVD), hot-filament CVD, or sputtering. In one aspect, the protective layer 116 may include deposition of Si₃N₄. In one aspect, the protective layer 116 forms an insulating layer. In one aspect, the protective layer 116 forms an insulator. In one aspect, the protective layer 116 may be a dielectric.

In aspects of the transistor 100 of the disclosure, the spacer layer 117 may be formed over the gate 114 between the source 110 and the drain 112. In one aspect, the spacer layer 117 may include a layer of non-conducting material such as a dielectric. In one aspect, the spacer layer 117 may include a number of different layers of dielectrics or a combination of dielectric layers. In one aspect, the spacer layer 117 may be many different thicknesses, with a suitable range of thicknesses being approximately 0.05 to 2 microns.

In one aspect, the protective layer 116 may be a protective layer, a spacer layer, an overlayer, a dielectric layer, and/or the like. In one aspect, the protective layer 116 may include a material such as a dielectric or insulating material, such as SIN, SiO2, etc. In some aspects the protective layer 116 may be a passivation layer, such as SiN, AlO, SiO, SiO₂, AlN, SiON, or the like, or a combination incorporating multiple layers thereof.

In one aspect, the spacer layer 117 may be a protective layer, a spacer layer, an overlayer, a dielectric layer, and/or the like. In one aspect, the spacer layer 117 may include a material such as a dielectric or insulating material, such as SiN, SiO2, etc. In some aspects the spacer layer 117 may be a passivation layer, such as SiN, AlO, SiO, SiO₂, AlN, SiON, or the like, or a combination incorporating multiple layers thereof.

In one aspect, the layer 118 may be a protective layer, a spacer layer, an overlayer, a dielectric layer, and/or the like. In one aspect, the layer 118 may include a material such as a dielectric or insulating material, such as SiN, SiO2, etc. In some aspects the layer 118 may be a passivation layer, such as SiN, AlO, SiO, SiO₂, AlN, SiON, or the like, or a combination incorporating multiple layers thereof.

In aspects of the transistor 100 of the disclosure, the channel layer 104 may be designed to be of the high purity type where the Fermi level is in the upper half of the bandgap, which minimizes slow trapping effects normally observed in GaN HEMTs. In this regard, the traps under the Fermi level are filled always and thus slow transients may be prevented. In some aspects, the channel layer 104 may be as thin as possible consistent with achieving good crystalline quality. Applicants have already demonstrated 0.4 μm layers with good quality.

In aspects of the transistor 100 of the disclosure, the nucleation layer 136 may include a Group III-nitride nucleation layer and/or channel layer 104 may be grown on the substrate layer 102 via an epitaxial crystal growth method, such as MOCVD (Metalorganic Chemical Vapor Deposition), HVPE (Hydride Vapor Phase Epitaxy) and/or MBE (Molecular Beam Epitaxy). The formation of the nucleation layer may depend on the material of the substrate layer 102.

In aspects of the transistor 100 of the disclosure, a gate contact may be provided for the gate 114 in between the source 110 and the drain 112. Furthermore, in certain aspects of the disclosure, the gate contact may be disposed on the barrier layer 108. In one aspect, the gate contact may be disposed directly on the barrier layer 108.

The gate 114 may be formed of platinum (Pt), nickel (Ni), and/or gold (Au), however, other metals known to one skilled in the art to achieve the Schottky effect, may be used. In one aspect, the gate 114 may include a Schottky gate contact that may have a three layer structure. Such a structure may have advantages because of the high adhesion of some materials. In one aspect, the gate 114 may further include an overlayer of highly conductive metal. In one aspect, the gate 114 may be configured as a T-shaped gate.

In aspects of the transistor 100 of the disclosure, one or more metal overlayers may be provided on one or more of the source 110, the drain 112, and the gate 114. The overlayers may be Au, Silver (Ag), Al, Pt, Ti, Si, Ni, Al, and/or Copper (Cu). Other suitable highly conductive metals may also be used for the overlayers.

In one aspect, the field plate 132 may be arranged on the spacer layer 117 between the gate 114 and the drain 112. In one aspect, the field plate 132 may be deposited on the spacer layer 117 between the gate 114 and the drain 112. In some aspects, the field plate 132 may be adjacent the gate 114 and the spacer layer 117 of dielectric material may be included at least partially over the gate 114 to isolate the gate 114 from the field plate 132. In some aspects, the field plate 132 may overlap the gate 114 and the spacer layer 117 of dielectric material may be included at least partially over the gate 114 to isolate the gate 114 from the field plate 132.

The field plate 132 may extend different distances from the edge of the gate 114, with a suitable range of distances being approximately 0.1 to 2 microns. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like.

In one aspect, the field plate 132 may be formed on the spacer layer 117 between the gate 114 and the drain 112, with the field plate 132 being in proximity to the gate 114 but not overlapping the gate 114. In one aspect, a space between the gate 114 and field plate 132 may be wide enough to isolate the gate 114 from the field plate 132, while being small enough to maximize a field effect provided by the field plate 132.

In certain aspects, the field plate 132 may reduce a peak operating electric field in the transistor 100. In certain aspects, the field plate 132 may reduce the peak operating electric field in the transistor 100 and may increase the breakdown voltage of the transistor 100. In certain aspects, the field plate 132 may reduce the peak operating electric field in the transistor 100 and may reduce trapping in the transistor 100. In certain aspects, the field plate 132 may reduce the peak operating electric field in the transistor 100 and may reduce leakage currents in the transistor 100.

In aspects of the transistor 100 of the disclosure, the source 110 and the drain 112 may be symmetrical with respect to the gate 114. In some switch device application aspects, the source 110 and the drain 112 may be symmetrical with respect to the gate 114.

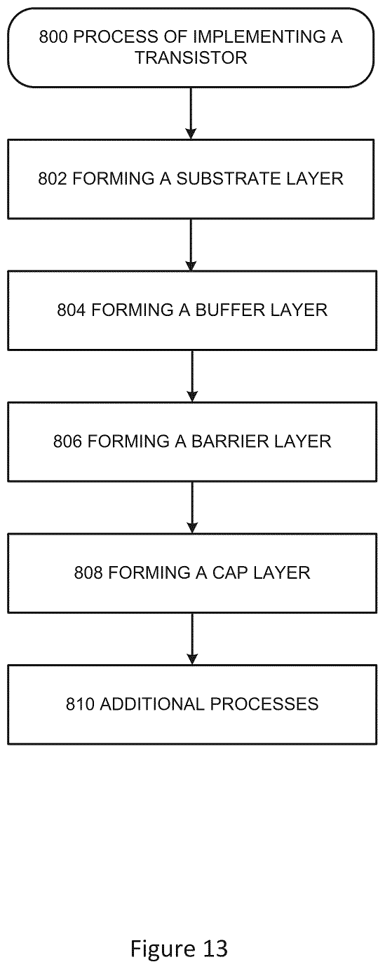

FIG. 13 shows an exemplary process of implementing a transistor according to the disclosure.

In particular, FIG. 13 shows an exemplary process of implementing a transistor 800 of the disclosure. In particular, the process of implementing a transistor 800 may be a process for making the transistor 100 of the disclosure. It should be noted that the process of implementing a transistor 800 is merely exemplary and may be modified consistent with the various aspects disclosed herein.

The process of implementing a transistor 800 may include forming a substrate layer 802. In particular, the forming a substrate layer 802 may include forming a substrate layer 102 as disclosed herein.

In aspects, the substrate layer 102 may be made of Silicon Carbide (SiC) or sapphire. In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. The substrate layer 102 may be formed of SiC selected from the group of 6H, 4H, 15R, 3C SiC, or the like. In another aspect, the substrate layer 102 may be GaAs, GaN, or other material suitable for the applications described herein. In another aspect, the substrate layer 102 may include spinel, ZnO, silicon, or any other material capable of supporting growth of Group III-nitride materials.

The process of implementing a transistor 800 may include forming a channel layer 804. In particular, the forming a channel layer 804 may include forming the channel layer 104 as disclosed herein.

In aspects, the channel layer 104 may be grown or deposited on the substrate layer 102. In one aspect, the channel layer 104 may be GaN. In another aspect, the channel layer 104 may be formed with LEO. In one aspect, the nucleation layer 136 may be formed on the substrate layer 102 and the channel layer 104 may be formed on the nucleation layer 136. The channel layer 104 may be grown or deposited on the nucleation layer 136. In one aspect, the channel layer 104 may be GaN. In another aspect, the channel layer 104 may be formed with LEO.

The process of implementing a transistor 800 may include forming a barrier layer 806. In particular, the forming a barrier layer 806 may include forming the barrier layer 108 as disclosed herein.

In aspects, the barrier layer 108 may be an n-type conductivity layer or may be undoped. In one aspect, the barrier layer 108 may be AlGaN. In one aspect, the barrier layer 108 may be formed directly on the channel layer 104. The barrier layer 108 may provide an additional layer between the channel layer 104 and the source 110, the drain 112, and the gate 114. The barrier layer 108 may be AlGaN, AlN, a Group III-nitride, InAlGaN, or another suitable material. In one aspect, the barrier layer 108 may be AlGaN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, a bandgap of the channel layer 104 may be less than a bandgap of the barrier layer 108. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, additional Group III-nitride layer(s) or region(s) and/or other layer(s) or region(s) of different materials are possible on the barrier layer 108 and/or in the overall structure. Any of the layers and/or regions can have uniform, non-uniform, graded and/or changing composition, thicknesses, and/or doping.

The process of implementing a transistor 800 may include forming a cap layer 808. In particular, the forming a cap layer 808 may include forming the cap layer 200 as disclosed herein.

In aspects, the forming a cap layer 808 may include the first processing step 401 illustrated in FIG. 5. In aspects, the cap layer 200 may be structured, configured, and/or arranged in a source access region and part of a drain access region as part of the first processing step 401 illustrated in FIG. 5. In other words, the cap layer 200 may be arranged on the upper barrier layer surface 308 and/or the entirety of the upper barrier layer surface 308.

In one aspect, the cap layer 200 may include the same material as the barrier layer 108. In one aspect, the cap layer 200 may include a different material than the barrier layer 108. In one aspect, the cap layer 200 may include a Group III-nitride material, such as AlGaN that is regrown and may have the same composition as the barrier layer 108. In one aspect, the cap layer 200 may include a Group III-nitride material, such as AlGaN, that is regrown and may have a different composition as the barrier layer 108.

In some aspects, the cap layer 200 can extend uniformly, non-uniformly, and/or a changing fashion with respect to composition, doping, and/or thickness. In aspects, the cap layer 200 may be formed using known semiconductor growth techniques such as Metalorganic Chemical Vapor Deposition (MOCVD), Hydride Vapor Phase Epitaxy (HVPE), Molecular Beam Epitaxy (MBE), and/or the like. In aspects, the cap layer 200 may be formed with Lateral Epitaxial Overgrowth (LEO). In aspects, the cap layer 200 may include hot wall epitaxy.

In aspects, the forming a cap layer 808 may include the second processing step 402 illustrated in FIG. 6. In particular, the cap layer 200 may be etched in the source access region and part of the drain access region as part of the second processing step 402 illustrated in FIG. 6. By removing the cap layer 200 in the source access region and part of the drain access region, a 2DEG concentration of the transistor 100 may be kept high in these regions for low on-state resistance and high power density. In aspects, this feature may decrease a peak electric field, increase off-state breakdown voltage, reduce Cg (gate capacitance) and may allow for higher operation voltage, higher frequency performance, higher power gain, and/or the like of the transistor 100. Further, etching the cap layer 200 may form the cap layer gate portion 142, the secondary gate cap layer portion 144, and/or the field plate cap layer portion 148. The second processing step 402 may be implemented before passivation layer deposition that may include the protective layer 116.

In aspects, the forming a cap layer 808 may include the third processing step 403 illustrated in FIG. 7. In particular, as part of the third processing step 403 illustrated in FIG. 7, the protective layer 116 may be arranged on the cap layer 200, the barrier layer 108, and/or the upper barrier layer surface 308. In aspects, the disclosed device structures and process of implementing device structures may include depositing a passivation layer after selectively remove the cap layer. In particular, the third processing step 403 may be implemented after the second processing step 402.

In aspects, the forming a cap layer 808 may include the fourth processing step 404 illustrated in FIG. 8. In particular, the fourth processing step 404 may include forming a gate opening 320 and a field plate opening 322. For example, a layer of photoresist may be formed on the protective layer 116 and patterned to form the gate opening 320 and the field plate opening 322. Thereafter, the protective layer 116 may be selectively etched through the gate opening 320 and the field plate opening 322, for example using a dry etch, a reactive ion etch, and/or inductively coupled plasma, and/or the like to form the gate opening 320 and the field plate opening 322 in the protective layer 116. In aspects, the gate opening 320 and/or the field plate opening 322 may partly form a double gate implementation of the gate 114.

In aspects, a sacrificial dielectric layer may be blanket deposited over the protective layer 116 to fill the gate opening 320 and the field plate opening 322. The sacrificial dielectric layer may be formed of the same material as the protective layer 116. For example, both the sacrificial dielectric layer and the protective layer 116 may be formed of silicon nitride.

In aspects, a sacrificial dielectric layer maybe anisotropically etched, for example using dry etch, a reactive ion etch, and/or inductively coupled plasma, to remove portions of the sacrificial dielectric layer except for side portions on inner surfaces of the gate opening 320 of the protective layer 116 and side portions on inner surfaces of the field plate opening 322 of the protective layer 116 to form a gate aperture and a field plate aperture having rounded or beveled edges. The protective layer 116 along with the side portions together form a surface dielectric layer on the upper barrier layer surface 308.

In aspects, the forming a cap layer 808 may include the fifth processing step 405 illustrated in FIG. 9. In particular, the fifth processing step 405 may include providing a metal, such as gold, that may be deposited and patterned to form the gate 114 on the protective layer 116. The gate 114 may extend through the gate opening 320 to contact the barrier layer 108. In particular, the lower gate surface 304 may extend through the gate opening 320 to contact the barrier layer 108.

In aspects, the forming a cap layer 808 may include the sixth processing step 406 illustrated in FIG. 10. In particular, the sixth processing step 406 may include forming the spacer layer 117. In particular, the spacer layer 117 may be blanket deposited over the protective layer 116 and the gate 114. The spacer layer 117 may extend through the field plate opening 322 to contact the barrier layer 108 and/or the cap layer 200.

In aspects, the forming a cap layer 808 may include the seventh processing step 407 illustrated in FIG. 11. In particular, the seventh processing step 407 may include forming the field plate 132. In particular, a metal, such as gold, may be deposited on the spacer layer 117 above the field plate opening 322 and patterned to form the field plate 132. The field plate 132 may be separated from the barrier layer 108 within the field plate opening 322 by a distance corresponding to a thickness of the spacer layer 117. The field plate 132 may be laterally spaced apart from the gate 114 approximately equal to the thickness of the spacer layer 117. Accordingly, the field plate 132 may be self-aligned to the gate 114. In aspects, the field plate 132, the gate opening 320, and the field plate opening 322 may partly form a double gate implementation of the gate 114.

In aspects, the forming a cap layer 808 may include the eighth processing step 408 illustrated in FIG. 12. In particular, the eighth processing step 408 may include forming a layer 118. In particular, the layer 118, such as a layer of SiON, may be formed over the field plate 132 and the spacer layer 117.

Further during the forming a cap layer 808, the gate 114 may be arranged on the barrier layer 108 between the source 110 and the drain 112. A layer of Ni, Pt, AU, or the like may be formed for the gate 114 by evaporative deposition or another technique. The gate structure may then be completed by deposition of Pt and Au, or other suitable materials. In some aspects, the contacts of the gate 114 may include Al, Ti, Si, Ni, and/or Pt. The gate 114 may extend on top of a spacer or the protective layer 116. The protective layer 116 may be etched and the gate 114 deposited such that the bottom of the gate 114 is on the surface of barrier layer 108. The metal forming the gate 114 may be patterned to extend across protective layer 116 so that the top of the gate 114 forms a field plate 132.

Further during the forming a cap layer 808, the field plate 132 may be arranged on top of another protective layer and may be separated from the gate 114. In one aspect, the field plate 132 may be deposited on the spacer layer 117 between the gate 114 and the drain 112. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like. In one aspect, a plurality of the field plates 132 may be used. In one aspect, a plurality of the field plates 132 may be used and each of the plurality of field plates 132 may be stacked with a dielectric material therebetween. In one aspect, the field plate 132 extends toward the edge of gate 114 towards the drain 112. In one aspect, the field plate 132 extends towards the source 110. In one aspect, the field plate 132 extends towards the drain 112 and towards the source 110. In another aspect, the field plate 132 does not extend toward the edge of gate 114. Finally, the structure may be covered with the spacer layer 117 such as silicon nitride. The spacer layer 117 may also be implemented similar to the protective layer 116. Moreover, it should be noted that the cross-sectional shape of the gate 114, shown in the Figures is exemplary. For example, the cross-sectional shape of the gate 114 in some aspects may not include the T-shaped extensions. Other constructions of the gate 114 may be utilized.

In one aspect, the cap layer 200 may include the same material as the barrier layer 108. In one aspect, the cap layer 200 may include a different material than the barrier layer 108. In one aspect, the cap layer 200 may include a Group III-nitride material, such as AlGaN that is regrown and may have the same composition as the barrier layer 108. In one aspect, the cap layer 200 may include a Group III-nitride material, such as AlGaN that is regrown and may have a different composition of AlGaN as the barrier layer 108. In some aspects, the cap layer 200 can extend uniformly, non-uniformly and/or changing fashion with respect to composition, doping and/or thickness.

The protective layer 116 may be formed. The protective layer 116 may be a passivation layer, such as SiN, AlO, SiO, SiO₂, AIN, SiON, or the like, or a combination incorporating multiple layers thereof, which may be deposited over the exposed surface of the barrier layer 108 and/or the cap layer 200.

Additionally, the process of implementing a transistor 800 may include additional processes 810. For example, the source 110 may be arranged on the barrier layer 108 and/or the channel layer 104. The source 110 may be an ohmic contact of a suitable material that may be annealed. For example, the source 110 may be annealed at a temperature of from about 500° C. to about 800° C. for about 2 minutes. However, other times and temperatures may also be utilized. Times from about 30 seconds to about 10 minutes may be, for example, acceptable. In some aspects, the source 110 may include Al, Ti, Si, Ni, and/or Pt. In one aspect, a region under the source 110 that is an N+ material may be formed in the barrier layer 108. In one aspect, a region under the drain 112 may be Si doped.

Further during the additional processes 810, the drain 112 may be arranged on the barrier layer 108 and/or the channel layer 104. Like the source 110, the drain 112 may be an ohmic contact of Ni or another suitable material, and may also be annealed in a similar fashion. In one aspect, an n+ implant may be used in conjunction with the barrier layer 108 and the contacts are made to the implant. In one aspect, a region under the drain 112 that is an N+ material may be formed in the barrier layer 108. In one aspect, a region under the drain 112 may be Si doped.

The source 110 and the drain 112 electrodes may be formed making ohmic contacts such that an electric current flows between the source 110 and drain 112 electrodes via a two-dimensional electron gas (2DEG) induced at the heterointerface 152 between the channel layer 104 and barrier layer 108 when a gate 114 electrode is biased at an appropriate level. In one aspect, the heterointerface 152 may be in the range of 0.005 μm to 0.007 μm, 0.007 μm to 0.009 μm, and 0.009 μm to 0.011 μm.

It should be noted that the steps of 800 may be performed in a different order consistent with the aspects described above. Moreover, the process of implementing a transistor 800 may be modified to have more or fewer process steps consistent with the various aspects disclosed herein.

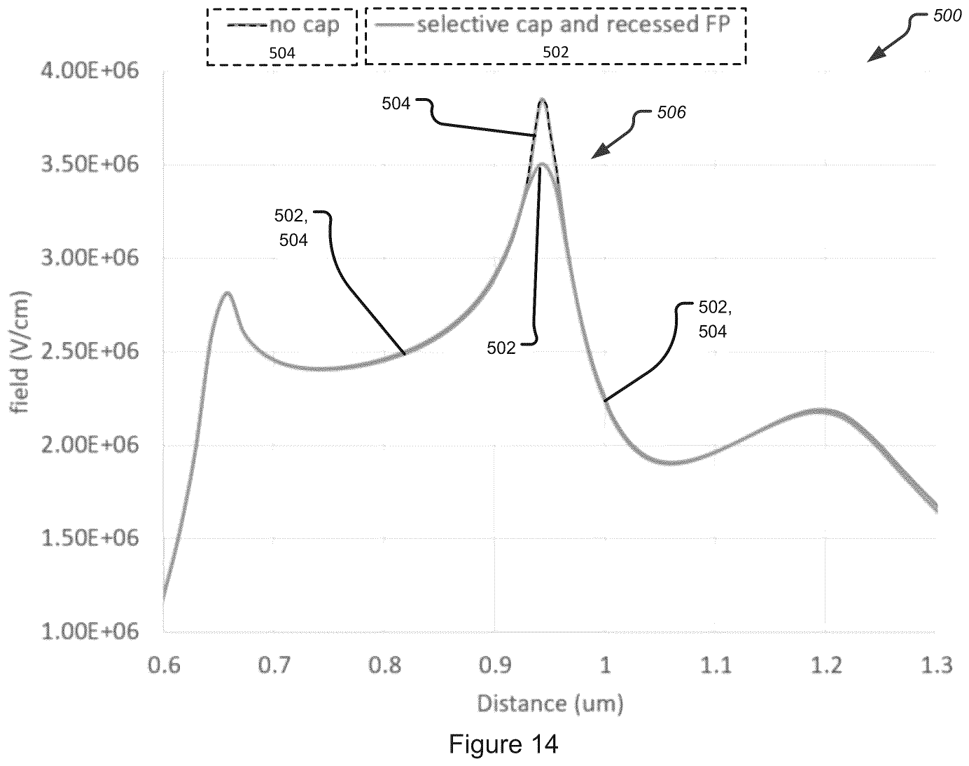

FIG. 14 illustrates a graph of the electric field versus distance comparing the transistor according to the disclosure and a commensurate transistor implemented without the cap layer.

In particular, FIG. 14 illustrates a graph 500 of the electric field versus distance comparing the transistor 100 implementing the cap layer 200 according to the disclosure and a commensurate transistor implemented without the cap layer 200. The graph 500 includes a vertical axis with the field in volts per centimeter (V/cm) and the horizontal axis provides a distance in microns from an edge of the source 110 of the transistor 100 implementing the cap layer 200 and an edge of a source of the commensurate transistor implemented without the cap layer 200.

In particular, line 502 (selective And recessed FP (field plate)) relates to the transistor 100 implementing the cap layer 200 according to the disclosure; and line 504 relates to a commensurate transistor implemented without the cap layer 200. As illustrated by the line 502 and the line 504, the transistor 100 implementing the cap layer 200 according to the disclosure generates a lower peak electric field 506. In particular aspects, the transistor 100 implementing the cap layer 200 according to the disclosure generates approximately 10% reduced peak electric field at certain distances.

Accordingly, the disclosure has set forth devices and processes that reduce generation of electric field and/or generation of parasitic capacitances to improve higher power performance in Group III-nitride HEMTs and/or the like. Further, the disclosure has set forth devices and processes that reduce generation of electric field and/or generation of parasitic capacitances to improve linearity in Group III-nitride HEMTs and/or the like. Further, the disclosure has set forth devices implementing selective cap layers to reduce generation of electric field. Further, the disclosure has set forth processes for implementing devices with selective cap layers to reduce generation of electric field. Additionally, the disclosure has set forth devices implementing selective cap layers to reduce generation of parasitic capacitances. Further, the disclosure has set forth processes for implementing devices with selective cap layers to reduce generation of parasitic capacitances. Further, the disclosure has set forth devices implementing selective cap layers for high breakdown voltage. Further, the disclosure has set forth processes for implementing devices with selective cap layers for high breakdown voltage. Additionally, the disclosure has set forth devices implementing selective cap layers for high power gain. Additionally, the disclosure has set forth processes for implementing devices with selective cap layers for high power gain.

The following are a number of nonlimiting EXAMPLES of aspects of the disclosure.

One EXAMPLE: a device includes a substrate. The device in addition includes a channel layer on the substrate. The device moreover includes a barrier layer on the channel layer. The device also includes a source electrically coupled to the barrier layer and/or the channel layer. The device further includes a gate at least partially on the barrier layer. The device in addition includes a drain electrically coupled to the barrier layer and/or the channel layer. The device moreover includes a cap layer structured, configured, and/or arranged under an edge of the gate at a drain side and the cap layer extending on the barrier layer at least from the edge of the gate on the drain side. The device also includes where the cap layer does not extend to an edge of the gate on a source side.

The above-noted EXAMPLE may further include any one or a combination of more than one of the following EXAMPLES: The device of the above-noted EXAMPLE where the cap layer is structured, configured, and/or arranged under a lower edge of the gate at the drain side adjacent and/or on the barrier layer. The device of the above-noted EXAMPLE where the gate is partially arranged directly on the barrier layer; and where the gate is partially arranged directly on the cap layer. The device of the above-noted EXAMPLE where the cap layer comprises an end portion; and where the gate is arranged on the end portion of the cap layer. The device of the above-noted EXAMPLE where the cap layer comprises an end portion; and where the end portion of the cap layer is arranged between the edge of the gate on the drain side and the edge of the gate on the source side. The device of the above-noted EXAMPLE where the cap layer comprises an end portion; and where the end portion of the cap layer is arranged between a lower edge of the gate on the drain side and a lower edge of the gate on the source side. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at the drain side. The device of the above-noted EXAMPLE where the cap layer is structured, configured, and/or arranged under a lower edge of the gate at the drain side adjacent and on the barrier layer. The device of the above-noted EXAMPLE where the cap layer comprises an etched structure. The device of the above-noted EXAMPLE where the cap layer comprises a single layer of material. The device of the above-noted EXAMPLE where the cap layer comprises multiple layers of material. The device of the above-noted EXAMPLE where the cap layer comprises a thickness in a range from 1 nm to 30 nm. The device of the above-noted EXAMPLE where the cap layer comprises AlxGa1−xN, where 0≤x≤1. The device of the above-noted EXAMPLE where the cap layer comprises GaN. The device of the above-noted EXAMPLE where the cap layer comprises AlGaN. The device of the above-noted EXAMPLE where the cap layer is arranged on an upper barrier layer surface of the barrier layer. The device of the above-noted EXAMPLE where the cap layer is structured and arranged partially in a protective layer and/or partially under the protective layer. The device of the above-noted EXAMPLE where the gate comprises a lower gate surface on an upper barrier layer surface; and where the lower gate surface is arranged on the cap layer. The device of the above-noted EXAMPLE where a majority of the lower gate surface is arranged on an upper barrier layer surface; and where minority part of the lower gate surface is arranged on the cap layer. The device of the above-noted EXAMPLE where the gate comprises a secondary lower gate surface arranged vertically above the lower gate surface; and where the cap layer is arranged under the secondary lower gate surface. The device of the above-noted EXAMPLE where the cap layer is structured, configured, and/or arranged under a lower edge of the gate at the drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at the drain side. The device of the above-noted EXAMPLE where the cap layer is structured, configured, and/or arranged under a lower edge of the gate at the drain side adjacent and on the barrier layer. The device of the above-noted EXAMPLE includes a field plate, where the cap layer is arranged at least partially under the field plate. The device of the above-noted EXAMPLE where the cap layer is structured, configured, and/or arranged under a lower edge of the gate at the drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at the drain side. The device of the above-noted EXAMPLE where the cap layer is structured, configured, and/or arranged under a lower edge of the gate at the drain side adjacent and on the barrier layer. The device of the above-noted EXAMPLE where a protective layer is arranged on the cap layer; and where the protective layer comprises a gate opening and a field plate opening. The device of the above-noted EXAMPLE where the gate opening and the field plate opening comprise etched structures. The device of the above-noted EXAMPLE includes a layer arranged over the field plate and a spacer layer. The device of the above-noted EXAMPLE where the cap layer is structured, configured, and/or arranged to reduce a peak electric field more than 5%. The device of the above-noted EXAMPLE where the cap layer is structured, configured, and/or arranged to decrease Cgd (gate drain capacitance). The device of the above-noted EXAMPLE comprising a transistor. The device of the above-noted EXAMPLE comprising a high-electron mobility transistor (HEMT).

One EXAMPLE: a process includes providing a substrate. The process in addition includes arranging a channel layer on the substrate. The process moreover includes arranging a barrier layer on the channel layer. The process also includes electrically coupling a source to the barrier layer and/or the channel layer. The process further includes electrically coupling a drain to the barrier layer and/or the channel layer. The process in addition includes forming a cap layer on the barrier layer. The process moreover includes arranging a gate at least partially on the barrier layer and arranging an edge of the gate at a drain side on the cap layer. The process also includes where the cap layer extends at least from an edge of the gate on a drain side and the cap layer does not extend to an edge of the gate on a source side.

The above-noted EXAMPLE may further include any one or a combination of more than one of the following EXAMPLES: The process of the above-noted EXAMPLE includes forming the cap layer under a lower edge of the gate at the drain side adjacent and/or on the barrier layer. The process of the above-noted EXAMPLE includes: arranging the gate partially directly on the barrier layer; and arranging the gate partially directly on the cap layer. The process of the above-noted EXAMPLE where the cap layer comprises an end portion; and where the gate is arranged on the end portion of the cap layer. The process of the above-noted EXAMPLE where the cap layer comprises an end portion; and where the end portion of the cap layer is arranged between the edge of the gate on the drain side and the edge of the gate on the source side. The process of the above-noted EXAMPLE where the cap layer comprises an end portion; and where the end portion of the cap layer is arranged between a lower edge of the gate on the drain side and a lower edge of the gate on the source side. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes forming the cap layer by etching the cap layer. The process of the above-noted EXAMPLE includes forming the cap layer with a single layer of material. The process of the above-noted EXAMPLE includes forming the cap layer with multiple layers of material. The process of the above-noted EXAMPLE includes forming the cap layer with a thickness in a range from 1 nm to 30 nm. The process of the above-noted EXAMPLE where the cap layer comprises AlxGa1−xN, where 0≤x≤1. The process of the above-noted EXAMPLE where the cap layer comprises GaN. The process of the above-noted EXAMPLE where the cap layer comprises AlGaN. The process of the above-noted EXAMPLE includes forming the cap layer on an upper barrier layer surface of the barrier layer. The process of the above-noted EXAMPLE includes forming the cap layer partially in a protective layer and/or partially under the protective layer. The process of the above-noted EXAMPLE where the gate comprises a lower gate surface on an upper barrier layer surface; and where the lower gate surface is arranged on the cap layer. The process of the above-noted EXAMPLE where a majority of the lower gate surface is arranged on an upper barrier layer surface; and where minority part of the lower gate surface is arranged on the cap layer. The process of the above-noted EXAMPLE where the gate comprises a secondary lower gate surface arranged vertically above the lower gate surface; and where the cap layer is arranged under the secondary lower gate surface. The process of the above-noted EXAMPLE includes forming the cap layer under a lower edge of the gate at the drain side adjacent and/or on the barrier layer. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes forming a field plate, where the cap layer is arranged at least partially under the field plate. The process of the above-noted EXAMPLE includes forming the cap layer under a lower edge of the gate at the drain side adjacent and/or on the barrier layer. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes: arranging a protective layer on the cap layer; and forming a gate opening and a field plate opening in the protective layer. The process of the above-noted EXAMPLE includes forming etching the gate opening and the field plate opening in the protective layer. The process of the above-noted EXAMPLE includes arranging a layer over the field plate and a spacer layer. The process of the above-noted EXAMPLE where the cap layer is structured, configured, and/or arranged to reduce a peak electric field more than 5%. The process of the above-noted EXAMPLE where the cap layer is structured, configured, and/or arranged to decrease Cgd (gate drain capacitance). The process of the above-noted EXAMPLE where the device comprises a transistor. The process of the above-noted EXAMPLE where the device comprises a high-electron mobility transistor (HEMT).

One EXAMPLE: a device includes a substrate. The device in addition includes a channel layer on the substrate. The device moreover includes a barrier layer on the channel layer. The device also includes a source electrically coupled to the barrier layer and/or the channel layer. The device further includes a gate at least partially on the barrier layer. The device in addition includes a drain electrically coupled to the barrier layer and/or the channel layer. The device moreover includes a cap layer structured, configured, and/or arranged under an edge of the gate. The device also includes where the cap layer comprises an end portion. The device further includes where the gate is arranged on the end portion of the cap layer.

The above-noted EXAMPLE may further include any one or a combination of more than one of the following EXAMPLES: The device of the above-noted EXAMPLE where the cap layer is structured, configured, and/or arranged under a lower edge of the gate at a drain side adjacent and/or on the barrier layer. The device of the above-noted EXAMPLE where the gate is partially arranged directly on the barrier layer; and where the gate is partially arranged directly on the cap layer. The device of the above-noted EXAMPLE where the cap layer does not extend to an edge of the gate on a source side. The device of the above-noted EXAMPLE where the cap layer comprises an end portion; and where the end portion of the cap layer is arranged between the edge of the gate on a drain side and the edge of the gate on a source side. The device of the above-noted EXAMPLE where the cap layer comprises an end portion; and where the end portion of the cap layer is arranged between a lower edge of the gate on a drain side and a lower edge of the gate on a source side. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at a drain side. The device of the above-noted EXAMPLE where the cap layer is structured, configured, and/or arranged under a lower edge of the gate at a drain side adjacent and on the barrier layer. The device of the above-noted EXAMPLE where the cap layer comprises an etched structure. The device of the above-noted EXAMPLE where the cap layer comprises a single layer of material. The device of the above-noted EXAMPLE where the cap layer comprises multiple layers of material. The device of the above-noted EXAMPLE where the cap layer comprises a thickness in a range from 1 nm to 30 nm. The device of the above-noted EXAMPLE where the cap layer comprises AlxGa1−xN, where 0≤x≤1. The device of the above-noted EXAMPLE where the cap layer comprises GaN. The device of the above-noted EXAMPLE where the cap layer comprises AlGaN. The device of the above-noted EXAMPLE where the cap layer is arranged on an upper barrier layer surface of the barrier layer. The device of the above-noted EXAMPLE where the cap layer is structured and arranged partially in a protective layer and/or partially under the protective layer. The device of the above-noted EXAMPLE where the gate comprises a lower gate surface on an upper barrier layer surface; and where the lower gate surface is arranged on the cap layer. The device of the above-noted EXAMPLE where a majority of the lower gate surface is arranged on an upper barrier layer surface; and where minority part of the lower gate surface is arranged on the cap layer. The device of the above-noted EXAMPLE where the gate comprises a secondary lower gate surface arranged vertically above the lower gate surface; and where the cap layer is arranged under the secondary lower gate surface. The device of the above-noted EXAMPLE where the cap layer is structured, configured, and/or arranged under a lower edge of the gate at a drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at a drain side. The device of the above-noted EXAMPLE where the cap layer is structured, configured, and/or arranged under a lower edge of the gate at a drain side adjacent and on the barrier layer. The device of the above-noted EXAMPLE includes a field plate, where the cap layer is arranged at least partially under the field plate. The device of the above-noted EXAMPLE where the cap layer is structured, configured, and/or arranged under a lower edge of the gate at a drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at a drain side. The device of the above-noted EXAMPLE where the cap layer is structured, configured, and/or arranged under a lower edge of the gate at a drain side adjacent and on the barrier layer. The device of the above-noted EXAMPLE where a protective layer is arranged on the cap layer; and where the protective layer comprises a gate opening and a field plate opening. The device of the above-noted EXAMPLE where the gate opening and the field plate opening comprise etched structures. The device of the above-noted EXAMPLE includes a layer arranged over the field plate and a spacer layer. The device of the above-noted EXAMPLE where the cap layer is structured, configured, and/or arranged to reduce a peak electric field more than 5%. The device of the above-noted EXAMPLE where the cap layer is structured, configured, and/or arranged to decrease Cgd (gate drain capacitance). The device of the above-noted EXAMPLE comprising a transistor. The device of the above-noted EXAMPLE comprising a high-electron mobility transistor (HEMT).

One EXAMPLE: a process includes providing a substrate. The process in addition includes arranging a channel layer on the substrate. The process moreover includes arranging a barrier layer on the channel layer. The process also includes electrically coupling a source to the barrier layer and/or the channel layer. The process further includes electrically coupling a drain to the barrier layer and/or the channel layer. The process in addition includes forming a cap layer on the barrier layer. The process moreover includes arranging a gate at least partially on the barrier layer and arranging an edge of the gate at a drain side on the cap layer. The process also includes where the cap layer comprises an end portion. The process further includes where the gate is arranged on the end portion of the cap layer.

The above-noted EXAMPLE may further include any one or a combination of more than one of the following EXAMPLES: The process of the above-noted EXAMPLE includes forming the cap layer under a lower edge of the gate at the drain side adjacent and/or on the barrier layer. The process of the above-noted EXAMPLE includes: arranging the gate partially directly on the barrier layer; and arranging the gate partially directly on the cap layer. The process of the above-noted EXAMPLE where the cap layer extends at least from an edge of the gate on a drain side and the cap layer does not extend to an edge of the gate on a source side. The process of the above-noted EXAMPLE where the cap layer comprises an end portion; and where the end portion of the cap layer is arranged between the edge of the gate on the drain side and the edge of the gate on a source side. The process of the above- noted EXAMPLE where the cap layer comprises an end portion; and where the end portion of the cap layer is arranged between a lower edge of the gate on the drain side and a lower edge of the gate on a source side. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes forming the cap layer by etching the cap layer. The process of the above-noted EXAMPLE includes forming the cap layer with a single layer of material. The process of the above-noted EXAMPLE includes forming the cap layer with multiple layers of material. The process of the above-noted EXAMPLE includes forming the cap layer with a thickness in a range from 1 nm to 30 nm. The process of the above-noted EXAMPLE where the cap layer comprises AlxGa1−xN, where 0≤x≤1. The process of the above-noted EXAMPLE where the cap layer comprises GaN. The process of the above-noted EXAMPLE where the cap layer comprises AlGaN. The process of the above-noted EXAMPLE includes forming the cap layer on an upper barrier layer surface of the barrier layer. The process of the above-noted EXAMPLE includes forming the cap layer partially in a protective layer and/or partially under the protective layer. The process of the above-noted EXAMPLE where the gate comprises a lower gate surface on an upper barrier layer surface; and where the lower gate surface is arranged on the cap layer. The process of the above-noted EXAMPLE where a majority of the lower gate surface is arranged on an upper barrier layer surface; and where minority part of the lower gate surface is arranged on the cap layer. The process of the above-noted EXAMPLE where the gate comprises a secondary lower gate surface arranged vertically above the lower gate surface; and where the cap layer is arranged under the secondary lower gate surface. The process of the above-noted EXAMPLE includes forming the cap layer under a lower edge of the gate at the drain side adjacent and/or on the barrier layer. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes forming a field plate, where the cap layer is arranged at least partially under the field plate. The process of the above-noted EXAMPLE includes forming the cap layer under a lower edge of the gate at the drain side adjacent and/or on the barrier layer. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes: arranging a protective layer on the cap layer; and forming a gate opening and a field plate opening in the protective layer. The process of the above-noted EXAMPLE includes forming etching the gate opening and the field plate opening in the protective layer. The process of the above-noted EXAMPLE includes arranging a layer over the field plate and a spacer layer. The process of the above-noted EXAMPLE where the cap layer is structured, configured, and/or arranged to reduce a peak electric field more than 5%. The process of the above-noted EXAMPLE where the cap layer is structured, configured, and/or arranged to decrease Cgd (gate drain capacitance). The process of the above-noted EXAMPLE where the device comprises a transistor. The process of the above-noted EXAMPLE where the device comprises a high-electron mobility transistor (HEMT).

One EXAMPLE: a device includes a substrate. The device in addition includes a channel layer on the substrate. The device moreover includes a barrier layer on the channel layer. The device also includes a source electrically coupled to the channel layer. The device further includes a gate comprising a bottom surface on the barrier layer. The device in addition includes a drain electrically coupled to the channel layer. The device moreover includes a cap layer on the barrier layer, where a portion of the bottom surface of the gate is directly on at least a portion of the cap layer.

The above-noted EXAMPLE may further include any one or a combination of more than one of the following EXAMPLES: The device of the above-noted EXAMPLE where the cap layer comprises multiple layers and subset of the multiple layers of the cap layer are under the gate. The device of the above-noted EXAMPLE where the cap layer comprises multiple layers and all of the multiple layers of the cap layer are under the gate. The device of the above-noted EXAMPLE where the barrier layer comprises multiple layers. The device of the above-noted EXAMPLE includes intervening layers between the gate the barrier layer. The device of the above-noted EXAMPLE where the cap layer is structured, configured, and/or arranged under a lower edge of the gate at a drain side adjacent and/or on the barrier layer. The device of the above-noted EXAMPLE where the gate is partially arranged directly on the barrier layer; and where the gate is partially arranged directly on the cap layer. The device of the above-noted EXAMPLE where the cap layer does not extend to an edge of the gate on a source side. The device of the above-noted EXAMPLE where the cap layer comprises an end portion; and where the end portion of the cap layer is arranged between a lower edge of the gate on a drain side and a lower edge of the gate on a source side. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at a drain side. The device of the above-noted EXAMPLE where the cap layer is structured, configured, and/or arranged under a lower edge of the gate at a drain side adjacent and on the barrier layer. The device of the above-noted EXAMPLE where the cap layer comprises an etched structure. The device of the above-noted EXAMPLE where the cap layer comprises a single layer of material. The device of the above-noted EXAMPLE where the cap layer comprises multiple layers of material. The device of the above-noted EXAMPLE where the cap layer comprises a thickness in a range from 1 nm to 30 nm. The device of the above-noted EXAMPLE where the cap layer comprises AlxGa1−xN, where 0≤x≤1. The device of the above-noted EXAMPLE where the cap layer comprises GaN. The device of the above-noted EXAMPLE where the cap layer comprises AlGaN. The device of the above-noted EXAMPLE where the cap layer is arranged on an upper barrier layer surface of the barrier layer. The device of the above-noted EXAMPLE where the cap layer is structured and arranged partially in a protective layer and/or partially under the protective layer. The device of the above-noted EXAMPLE where the gate comprises a lower gate surface on an upper barrier layer surface; and where the lower gate surface is arranged on the cap layer. The device of the above-noted EXAMPLE where a majority of the lower gate surface is arranged on an upper barrier layer surface; and where minority part of the lower gate surface is arranged on the cap layer. The device of the above-noted EXAMPLE where the gate comprises a secondary lower gate surface arranged vertically above the lower gate surface; and where the cap layer is arranged under the secondary lower gate surface. The device of the above-noted EXAMPLE where the cap layer is structured, configured, and/or arranged under a lower edge of the gate at a drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at a drain side. The device of the above-noted EXAMPLE where the cap layer is structured, configured, and/or arranged under a lower edge of the gate at a drain side adjacent and on the barrier layer. The device of the above-noted EXAMPLE includes a field plate, where the cap layer is arranged at least partially under the field plate. The device of the above-noted EXAMPLE where the cap layer is structured, configured, and/or arranged under a lower edge of the gate at a drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at a drain side. The device of the above-noted EXAMPLE where the cap layer is structured, configured, and/or arranged under a lower edge of the gate at a drain side adjacent and on the barrier layer. The device of the above-noted EXAMPLE where a protective layer is arranged on the cap layer; and where the protective layer comprises a gate opening and a field plate opening. The device of the above-noted EXAMPLE where the gate opening and the field plate opening comprise etched structures. The device of the above-noted EXAMPLE includes a layer arranged over the field plate and a spacer layer. The device of the above-noted EXAMPLE where the cap layer is structured, configured, and/or arranged to reduce a peak electric field more than 5%. The device of the above-noted EXAMPLE where the cap layer is structured, configured, and/or arranged to decrease Cgd (gate drain capacitance). The device of the above-noted EXAMPLE comprising a transistor. The device of the above-noted EXAMPLE comprising a high-electron mobility transistor (HEMT).

One EXAMPLE: a process includes providing a substrate. The process in addition includes arranging a channel layer on the substrate. The process moreover includes arranging a barrier layer on the channel layer. The process also includes electrically coupling a source electrically coupled to the channel layer. The process further includes electrically coupling a drain to the barrier layer and/or the channel layer. The process in addition includes forming a cap layer on the barrier layer. The process moreover includes arranging a gate comprising a bottom surface on the barrier layer. The process also includes where a portion of the bottom surface of the gate is directly on at least a portion of the cap layer.

The above-noted EXAMPLE may further include any one or a combination of more than one of the following EXAMPLES: The process of the above-noted EXAMPLE where the cap layer comprises multiple layers and subset of the multiple layers of the cap layer are under the gate. The process of the above-noted EXAMPLE where the cap layer comprises multiple layers and all of the multiple layers of the cap layer are under the gate. The process of the above-noted EXAMPLE where the barrier layer comprises multiple layers. The process of the above-noted EXAMPLE includes intervening layers between the gate the barrier layer. The process of the above-noted EXAMPLE includes: arranging the gate partially directly on the barrier layer; and arranging the gate partially directly on the cap layer. The process of the above-noted EXAMPLE where the cap layer extends at least from an edge of the gate on a drain side and the cap layer does not extend to an edge of the gate on a source side. The process of the above-noted EXAMPLE where the cap layer comprises an end portion; and where the end portion of the cap layer is arranged between the edge of the gate on the drain side and the edge of the gate on a source side. The process of the above-noted EXAMPLE where the cap layer comprises an end portion; and where the end portion of the cap layer is arranged between a lower edge of the gate on the drain side and a lower edge of the gate on a source side. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes forming the cap layer under a lower edge of the gate at the drain side adjacent and/or on the barrier layer. The process of the above-noted EXAMPLE includes forming the cap layer by etching the cap layer. The process of the above-noted EXAMPLE includes forming the cap layer with a single layer of material. The process of the above-noted EXAMPLE includes forming the cap layer with multiple layers of material. The process of the above-noted EXAMPLE includes forming the cap layer with a thickness in a range from 1 nm to 30 nm. The process of the above-noted EXAMPLE where the cap layer comprises AlxGa1−xN, where 0≤x≤1. The process of the above-noted EXAMPLE where the cap layer comprises GaN. The process of the above-noted EXAMPLE where the cap layer comprises AlGaN. The process of the above-noted EXAMPLE includes forming the cap layer on an upper barrier layer surface of the barrier layer. The process of the above-noted EXAMPLE includes forming the cap layer partially in a protective layer and/or partially under the protective layer. The process of the above-noted EXAMPLE where the gate comprises a lower gate surface on an upper barrier layer surface; and where the lower gate surface is arranged on the cap layer. The process of the above-noted EXAMPLE where a majority of the lower gate surface is arranged on an upper barrier layer surface; and where minority part of the lower gate surface is arranged on the cap layer. The process of the above-noted EXAMPLE where the gate comprises a secondary lower gate surface arranged vertically above the lower gate surface; and where the cap layer is arranged under the secondary lower gate surface. The process of the above-noted EXAMPLE includes forming the cap layer under a lower edge of the gate. The process of the above-noted EXAMPLE includes forming a field plate, where the cap layer is arranged at least partially under the field plate. The process of the above-noted EXAMPLE includes forming the cap layer under a lower edge of the gate. The process of the above-noted EXAMPLE includes: arranging a protective layer on the cap layer; and forming a gate opening and a field plate opening in the protective layer. The process of the above-noted EXAMPLE includes forming etching the gate opening and the field plate opening in the protective layer. The process of the above-noted EXAMPLE includes arranging a layer over the field plate and a spacer layer. The process of the above-noted EXAMPLE where the cap layer is structured, configured, and/or arranged to reduce a peak electric field more than 5%. The process of the above-noted EXAMPLE where the cap layer is structured, configured, and/or arranged to decrease Cgd (gate drain capacitance). The process of the above-noted EXAMPLE where the device comprises a transistor. The process of the above-noted EXAMPLE where the device comprises a high-electron mobility transistor (HEMT).

One EXAMPLE: a device includes a substrate. The device in addition includes a channel layer on the substrate. The device moreover includes a barrier layer on the channel layer. The device also includes a source electrically coupled to the barrier layer and/or the channel layer. The device further includes a gate at least partially on the barrier layer. The device in addition includes a drain electrically coupled to the barrier layer and/or the channel layer. The device moreover includes a cap layer structured, configured, and/or arranged under a drain side of the gate and the cap layer is not arranged under a source side of the gate.

The above-noted EXAMPLE may further include any one or a combination of more than one of the following EXAMPLES: The device of the above-noted EXAMPLE where the cap layer is structured, configured, and/or arranged under a lower edge of the gate at the drain side adjacent and/or on the barrier layer. The device of the above-noted EXAMPLE where the gate is partially arranged directly on the barrier layer; and where the gate is partially arranged directly on the cap layer. The device of the above-noted EXAMPLE where the cap layer comprises an end portion; and where the gate is arranged on the end portion of the cap layer. The device of the above-noted EXAMPLE where the cap layer comprises an end portion; and where the end portion of the cap layer is arranged between an edge of the gate on the drain side and the edge of the gate on the source side. The device of the above-noted EXAMPLE where the cap layer comprises an end portion; and where the end portion of the cap layer is arranged between a lower edge of the gate on the drain side and a lower edge of the gate on the source side. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at the drain side. The device of the above-noted EXAMPLE where the cap layer is structured, configured, and/or arranged under a lower edge of the gate at the drain side adjacent and on the barrier layer. The device of the above-noted EXAMPLE where the cap layer comprises an etched structure. The device of the above-noted EXAMPLE where the cap layer comprises a single layer of material. The device of the above-noted EXAMPLE where the cap layer comprises multiple layers of material. The device of the above-noted EXAMPLE where the cap layer comprises a thickness in a range from 1 nm to 30 nm. The device of the above-noted EXAMPLE where the cap layer comprises AlxGa1−xN, where 0≤x≤1. The device of the above-noted EXAMPLE where the cap layer comprises GaN. The device of the above-noted EXAMPLE where the cap layer comprises AlGaN. The device of the above-noted EXAMPLE where the cap layer is arranged on an upper barrier layer surface of the barrier layer. The device of the above-noted EXAMPLE where the cap layer is structured and arranged partially in a protective layer and/or partially under the protective layer. The device of the above-noted EXAMPLE where the gate comprises a lower gate surface on an upper barrier layer surface; and where the lower gate surface is arranged on the cap layer. The device of the above-noted EXAMPLE where a majority of the lower gate surface is arranged on an upper barrier layer surface; and where minority part of the lower gate surface is arranged on the cap layer. The device of the above-noted EXAMPLE where the gate comprises a secondary lower gate surface arranged vertically above the lower gate surface; and where the cap layer is arranged under the secondary lower gate surface. The device of the above-noted EXAMPLE where the cap layer is structured, configured, and/or arranged under a lower edge of the gate at the drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at the drain side. The device of the above-noted EXAMPLE where the cap layer is structured, configured, and/or arranged under a lower edge of the gate at the drain side adjacent and on the barrier layer. The device of the above-noted EXAMPLE includes a field plate, where the cap layer is arranged at least partially under the field plate. The device of the above-noted EXAMPLE where the cap layer is structured, configured, and/or arranged under a lower edge of the gate at the drain side adjacent and/or on the barrier layer. The device of the above-noted EXAMPLE where the cap layer is structured, configured, and/or arranged under a lower edge of the gate. The device of the above-noted EXAMPLE where the cap layer is structured, configured, and/or arranged under a lower edge of the gate at the drain side. The device of the above-noted EXAMPLE where the cap layer is structured, configured, and/or arranged under a lower edge of the gate at the drain side adjacent and on the barrier layer. The device of the above-noted EXAMPLE where a protective layer is arranged on the cap layer; and where the protective layer comprises a gate opening and a field plate opening. The device of the above-noted EXAMPLE where the gate opening and the field plate opening comprise etched structures. The device of the above-noted EXAMPLE includes a layer arranged over the field plate and a spacer layer. The device of the above-noted EXAMPLE where the cap layer is structured, configured, and/or arranged to reduce a peak electric field more than 5%. The device of the above-noted EXAMPLE where the cap layer is structured, configured, and/or arranged to decrease Cgd (gate drain capacitance). The device of the above-noted EXAMPLE comprising a transistor. The device of the above-noted EXAMPLE comprising a high-electron mobility transistor (HEMT).

One EXAMPLE: a process includes providing a substrate. The process in addition includes arranging a channel layer on the substrate. The process moreover includes arranging a barrier layer on the channel layer. The process also includes electrically coupling a source to the barrier layer and/or the channel layer. The process further includes electrically coupling a drain to the barrier layer and/or the channel layer. The process in addition includes forming a cap layer on the barrier layer. The process moreover includes arranging a gate at least partially on the barrier layer. The process also includes where the cap layer is structured, configured, and/or arranged under a drain side of the gate and the cap layer is not arranged under a source side of the gate.

The above-noted EXAMPLE may further include any one or a combination of more than one of the following EXAMPLES: The process of the above-noted EXAMPLE includes forming the cap layer under a lower edge of the gate at the drain side adjacent and/or on the barrier layer. The process of the above-noted EXAMPLE includes: arranging the gate partially directly on the barrier layer; and arranging the gate partially directly on the cap layer. The process of the above-noted EXAMPLE where the cap layer comprises an end portion; and where the gate is arranged on the end portion of the cap layer. The process of the above-noted EXAMPLE where the cap layer comprises an end portion; and where the end portion of the cap layer is arranged between an edge of the gate on the drain side and the edge of the gate on the source side. The process of the above-noted EXAMPLE where the cap layer comprises an end portion; and where the end portion of the cap layer is arranged between a lower edge of the gate on the drain side and a lower edge of the gate on the source side. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes forming the cap layer by etching the cap layer. The process of the above-noted EXAMPLE includes forming the cap layer with a single layer of material. The process of the above-noted EXAMPLE includes forming the cap layer with multiple layers of material. The process of the above-noted EXAMPLE includes forming the cap layer with a thickness in a range from 1 nm to 30 nm. The process of the above-noted EXAMPLE where the cap layer comprises AlxGa1−xN, where 0≤x≤1. The process of the above-noted EXAMPLE where the cap layer comprises GaN. The process of the above-noted EXAMPLE where the cap layer comprises AlGaN. The process of the above-noted EXAMPLE includes forming the cap layer on an upper barrier layer surface of the barrier layer. The process of the above-noted EXAMPLE includes forming the cap layer partially in a protective layer and/or partially under the protective layer. The process of the above-noted EXAMPLE where the gate comprises a lower gate surface on an upper barrier layer surface; and where the lower gate surface is arranged on the cap layer. The process of the above-noted EXAMPLE where a majority of the lower gate surface is arranged on an upper barrier layer surface; and where minority part of the lower gate surface is arranged on the cap layer. The process of the above-noted EXAMPLE where the gate comprises a secondary lower gate surface arranged vertically above the lower gate surface; and where the cap layer is arranged under the secondary lower gate surface. The process of the above-noted EXAMPLE includes forming the cap layer under a lower edge of the gate at the drain side adjacent and/or on the barrier layer. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes forming a field plate, where the cap layer is arranged at least partially under the field plate. The process of the above-noted EXAMPLE includes forming the cap layer under a lower edge of the gate at the drain side adjacent and/or on the barrier layer. The process of the above-noted EXAMPLE includes forming the cap layer under a lower edge of the gate. The process of the above-noted EXAMPLE includes forming the cap layer under a lower edge of the gate at the drain side. The process of the above-noted EXAMPLE includes forming the cap layer under a lower edge of the gate at the drain side adjacent and on the barrier layer. The process of the above-noted EXAMPLE includes: arranging a protective layer on the cap layer; and forming a gate opening and a field plate opening in the protective layer. The process of the above-noted EXAMPLE includes forming etching the gate opening and the field plate opening in the protective layer. The process of the above-noted EXAMPLE includes arranging a layer over the field plate and a spacer layer. The process of the above-noted EXAMPLE where the cap layer is structured, configured, and/or arranged to reduce a peak electric field more than 5%. The process of the above-noted EXAMPLE where the cap layer is structured, configured, and/or arranged to decrease Cgd (gate drain capacitance). The process of the above-noted EXAMPLE where the device comprises a transistor. The process of the above-noted EXAMPLE where the device comprises a high-electron mobility transistor (HEMT).

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

1. A device comprising:
a substrate;
a channel layer on the substrate;
a barrier layer on the channel layer,
a source electrically coupled to the barrier layer and/or the channel layer;
a gate at least partially on the barrier layer;
a drain electrically coupled to the barrier layer and/or the channel layer; and
a cap layer structured, configured, and/or arranged under an edge of the gate at a drain side and the cap layer extending on the barrier layer at least from the edge of the gate on the drain side,
wherein the cap layer does not extend to an edge of the gate on a source side.

2. The device according to claim 1 wherein the cap layer is structured, configured, and/or arranged under a lower edge of the gate at the drain side adjacent and/or on the barrier layer.

3. The device according to claim 1
wherein the gate is partially arranged directly on the barrier layer; and
wherein the gate is partially arranged directly on the cap layer.

4. The device according to claim 1
wherein the cap layer comprises an end portion; and
wherein the gate is arranged on the end portion of the cap layer.

5. The device according to claim 1
wherein the cap layer comprises an end portion; and
wherein the end portion of the cap layer is arranged between the edge of the gate on the drain side and the edge of the gate on the source side.

6. The device according to claim 1
wherein the cap layer comprises an end portion; and
wherein the end portion of the cap layer is arranged between a lower edge of the gate on the drain side and a lower edge of the gate on the source side.

7. The device according to claim 1 wherein the cap layer is structured, configured, and/or arranged under a lower edge of the gate.

8. The device according to claim 1 wherein the cap layer is structured, configured, and/or arranged under a lower edge of the gate at the drain side.

9. The device according to claim 1 wherein the cap layer is structured, configured, and/or arranged under a lower edge of the gate at the drain side adjacent and on the barrier layer.

10. The device according to claim 1 wherein the cap layer comprises an etched structure.

11. The device according to claim 1 wherein the cap layer comprises a single layer of material.

12. The device according to claim 1 wherein the cap layer comprises multiple layers of material.

13. The device according to claim 1 wherein the cap layer comprises a thickness in a range from 1 nm to 30 nm.

14. The device according to claim 1 wherein the cap layer comprises AlxGa1−xN, where 0≤x≤1.

15. (canceled)

16. (canceled)

17. The device according to claim 1 wherein the cap layer is arranged on an upper barrier layer surface of the barrier layer.

18. The device according to claim 1 wherein the cap layer is structured and arranged partially in a protective layer and/or partially under the protective layer.

19. The device according to claim 1
wherein the gate comprises a lower gate surface on an upper barrier layer surface; and
wherein the lower gate surface is arranged on the cap layer.

20-25. (canceled)

26. The device according to claim 1 further comprising a field plate,
wherein the cap layer is arranged at least partially under the field plate.

27-148. (canceled)

149. A device comprising:
a substrate;
a channel layer on the substrate;
a barrier layer on the channel layer;
a source electrically coupled to the channel layer;
a gate comprising a bottom surface on the barrier layer;
a drain electrically coupled to the channel layer; and
a cap layer on the barrier layer, wherein a portion of the bottom surface of the gate is directly on at least a portion of the cap layer.

150. The device according to claim 149 wherein the cap layer comprises multiple layers and subset of the multiple layers of the cap layer are under the gate.

151. The device according to claim 149 wherein the cap layer comprises multiple layers and all of the multiple layers of the cap layer are under the gate.

152. The device according to claim 149 wherein the barrier layer comprises multiple layers.

153. The device according to claim 149 further comprising intervening layers between the gate the barrier layer.

154. The device according to claim 149 wherein the cap layer is structured, configured, and/or arranged under a lower edge of the gate at a drain side adjacent and/or on the barrier layer.

155. The device according to claim 149
wherein the gate is partially arranged directly on the barrier layer; and
wherein the gate is partially arranged directly on the cap layer.

156. The device according to claim 149
wherein the cap layer does not extend to an edge of the gate on a source side.

157. The device according to claim 149
wherein the cap layer comprises an end portion; and
wherein the end portion of the cap layer is arranged between a lower edge of the gate on a drain side and a lower edge of the gate on a source side.

158. The device according to claim 149 wherein the cap layer is structured, configured, and/or arranged under a lower edge of the gate.

159. The device according to claim 149 wherein the cap layer is structured, configured, and/or arranged under a lower edge of the gate at a drain side.

160. The device according to claim 149 wherein the cap layer is structured, configured, and/or arranged under a lower edge of the gate at a drain side adjacent and on the barrier layer.

161. The device according to claim 149 wherein the cap layer comprises an etched structure.

162. The device according to claim 149 wherein the cap layer comprises a single layer of material.

163. The device according to claim 149 wherein the cap layer comprises multiple layers of material.

164. The device according to claim 149 wherein the cap layer comprises a thickness in a range from 1 nm to 30 nm.

165. The device according to claim 149 wherein the cap layer comprises AlxGa1−xN, where 0≤x≤1.

166. (canceled)

167. (canceled)

168. The device according to claim 149 wherein the cap layer is arranged on an upper barrier layer surface of the barrier layer.

169. The device according to claim 149 wherein the cap layer is structured and arranged partially in a protective layer and/or partially under the protective layer.

170. The device according to claim 149
wherein the gate comprises a lower gate surface on an upper barrier layer surface; and
wherein the lower gate surface is arranged on the cap layer.

171-176. (canceled)

177. The device according to claim 149 further comprising a field plate,
wherein the cap layer is arranged at least partially under the field plate.

178-297. (canceled)
